(19) United States
(12) Patent Application Publication
(10) Pub. No.: US 2008/0241589 A1
(43) Pub. Date: Oct. 2, 2008

(54) ORGANIC ELECTROLUMINESCENT DEVICE

(75) Inventors: Hirofumi FUKUNAGA, Kanagawa (JP); Toshihiro ISE, Kanagawa (JP)

Correspondence Address: SUGHRUE-265550, 2100 PENNSYLVANIA AVE. NW, WASHINGTON, DC, 20037-3213, US

(73) Assignee: FUJIFILM CORPORATION, Tokyo (JP)

(21) Appl. No.: 12/055,473

(22) Filed: Mar. 26, 2008

(30) Foreign Application Priority Data
Mar. 26, 2007 (JP) 2007-078737

(51) Int. Cl. C09K 11/00; C07F 1/08; C07C 211/54; C07D 209/82; C07F 15/00

(52) U.S. Cl. 428/690; 548/402; 564/429; 548/440; 546/6

(57) ABSTRACT

An organic electroluminescent device is provided and includes: a pair of electrodes; and an organic compound layer between the pair of electrodes, the organic compound layer including a light-emitting layer. The at least one organic compound layer contains at least one of a compound represent by formula (I) and a compound represented by formula (II).

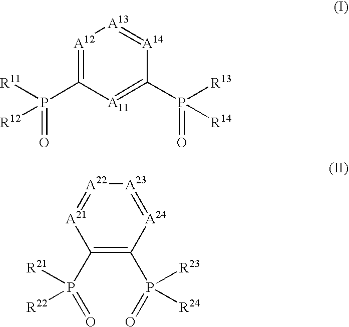

### BACKGROUND OF THE INVENTION

1. Field of the Invention

The present invention relates to an organic electroluminescent device capable of emitting light by converting electric energy into light.

2. Background Art

Organic electroluminescent devices (hereinafter also referred to as “organic EL devices”) are capable of obtaining emission of high luminance by low voltage driving, and actively researched and developed. An organic electroluminescent device includes a pair of electrodes and an organic compound layer between the pair of electrodes, and electrons injected from a cathode and holes injected from an anode are recombined in the organic compound layer, and generated energy of exciton is used for light-emitting.

Devices of high efficiency using phosphorescent materials are extensively developed in recent years, and light-emitting devices using iridium complexes and platinum complexes as phosphorescent materials are disclosed (for example, refer to U.S. Pat. No. 6,303,238 and WO 00/57676). However, further improvement of the performances of devices is desired, in particular, the compatibility of high efficiency and high durability of devices having emission in a blue region is strongly required.

As electron transporting materials for organic EL devices, aluminum complex materials of hydroxyquinoline have been used, but these materials are low in the level of the lowest triplet excited state (T₁ level) and phosphorescent emission is quenched in devices using phosphorescent material, so that the increase of efficiency has been difficult. This phenomenon is conspicuous in a case of emission in short wavelength, and the efficiency of device extremely lowers especially when the material is used in a blue-emitting phosphorescent device.

As a novel electron transporting material, phosphine oxide materials utilizing an electron withdrawing property of a P═O group are proposed (refer to JP-A-2002-63989, JP-A-2004-204140, JP-A-2006-73581, Organic Letters 2006, Vol. 8, No. 19, 4211-4214, Chemistry of Materials 2006, Vol. 18, No. 9, 2389-2396 and Applied Physics Letters, Vol. 88, 183503 (2006)). However, since hitherto known phosphine oxide materials have a biaryl skeleton and a polycyclic condensed skeleton, these materials are low in T₁ level and more improvements are required to be applied to blue phosphorescent devices. In addition, further improvement of durability of devices is necessary.

### SUMMARY OF THE INVENTION

An object of an illustrative, non-limiting embodiment of the invention is to provide an organic electroluminescent device having high emission efficiency and high durability. Another object is to provide a phosphine oxide compound suitably used in an organic electroluminescent device.

As a result of examinations for achieving the objects, the present inventors have found that the objects can be achieved by an organic EL device containing a phosphine oxide compound having a specific structure in an organic compound layer. That is, the objects can be achieved by the following means.

(1) An organic electroluminescent device including:

a pair of electrodes; and

an organic compound layer between the pair of electrodes, the organic compound layer including a light-emitting layer,

wherein the at least one organic compound layer contains at least one of a compound represent by formula (I) and a compound represented by formula (II):

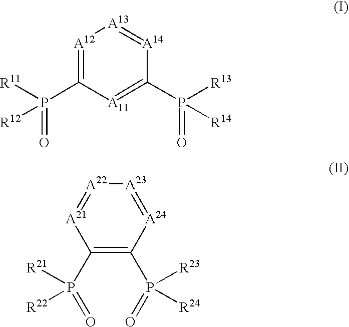

wherein R¹¹, R¹², R¹³ and R¹⁴ each independently represents a hydrogen atom or a substituent; A¹¹, A¹², A¹³ and A¹⁴ each independently represents a nitrogen atom or C—R¹⁰; R¹⁰ represents a hydrogen atom or a substituent, and when a plurality of R¹⁰'s are present, the plurality of R¹⁰'s may be the same or different and may be connected to each other to form a ring; R²¹, R²², R²³ and R²⁴ each independently represents a hydrogen atom or a substituent; A²¹, A²², A²³ and A²⁴ each independently represents a nitrogen atom or C—R²⁰; and R²⁰ represents a hydrogen atom or a substituent, and when a plurality of R²⁰'s are present, the plurality of R²⁰'s may be the same or different and may be connected to each other to form a ring.
(2) The organic electroluminescent device according to item (1) above, wherein each of the compound represented by formula (I) and a compound represented by formula (II) has a glass transition temperature of from 130 to 450° C.
(3) The organic electroluminescent device according to item (1) or (2) above, wherein the each of the compound represented by formula (I) and the compound represented by formula (II) has an energy level in the lowest triplet excited state of from 65 to 95 kcal/mol.
(4) The organic electroluminescent device according to any one of items (1) to (3) above, wherein the at least one organic compound layer contains a light-emitting material, and the light-emitting material contains a phosphorescent material.
(5) The organic electroluminescent device according to item (4) above, wherein the phosphorescent material is an iridium complex or a platinum complex.
(6) The organic electroluminescent device according to item (5) above, wherein the phosphorescent material is a platinum complex having a tetradentate ligand.
(7) The organic electroluminescent device according to item (6) above, wherein the platinum complex having a tetradentate ligand is represented by formula (C-1):

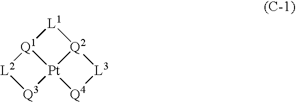

wherein Q¹, Q², Q³ and Q⁴ each independently represents a group coordinating to Pt; and L¹, L² and L³ each independently represents a single bond or a divalent linking group.
(8) The organic electroluminescent device according to item (6) or (7) above, wherein the platinum complex having a tetradentate ligand is represented by one of formulae (A), (B), (E) and (F):

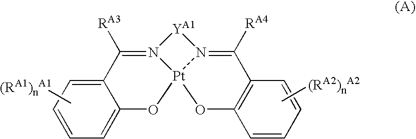

wherein R^{A3} and R^{A4} each independently represents a hydrogen atom or a substituent; R^{A1} and R^{A2} each independently represents a substituent, and when a plurality of R^{A1} and R^{A2} are present, the plurality of R^{A1} and R^{A2} may be the same or different, and R^{A1} and R^{A2} may be linked to each other to form a ring; n^{A1} and n^{A2} each independently represents an integer of from 0 to 4; and Y^{A1} represents a linking group;

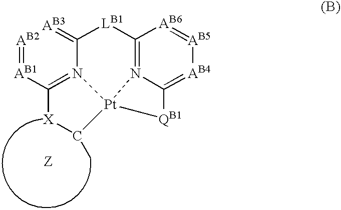

wherein A^{B1} to A^{B6} each independently represents C—R or N; R represents a hydrogen atom or a substituent; L^{B1} represents a single bond or a divalent linking group; X represents C or N; Z represents a 5- or 6-membered aromatic ring or aromatic heterocyclic ring formed together with X—C; and Q^{B1} represents an anionic group bonding to Pt;

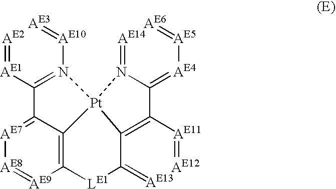

wherein A^{E1} to A^{E14} each independently represents C—R or N; R represents a hydrogen atom or a substituent; and LEl represents a single bond or a divalent linking group;

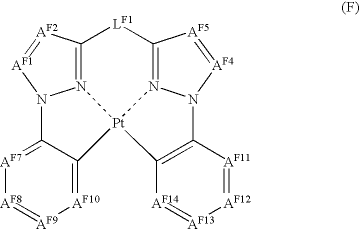

wherein A^{F1} to A^{F14} each independently represents C—R or N; R represents a hydrogen atom or a substituent; and L^{F1} represents a single bond or a divalent linking group.
(9) The organic electroluminescent device according to any one of items (1) to (8) above, wherein the at least one of the compound represented by formula (I) and the compound represented by formula (II) is contained in the light-emitting layer.
(10) The organic electroluminescent device according to any one of items (1) to (9) above, wherein the at least one organic compound layer includes a layer containing the at least one of the compound represented by formula (I) and the compound represented by formula (II), the layer being between the light-emitting layer and a cathode.
(11) The organic electroluminescent device according to any one of items (1) to (10) above, wherein the at least one organic compound layer includes an electron transporting layer, and the at least one of the compound represented by formula (I) and the compound represented by formula (II) is contained in the electron transporting layer.
(12) The organic electroluminescent device according to any one of items (1) to (11) above, wherein the at least one organic compound layer includes: a first layer containing the at least one of the compound represented by formula (I) and the compound represented by formula (II), the first layer being between the light-emitting layer and a cathode; and a second layer between the first layer and the light-emitting layer.
(13) A compound represented by formula (I):

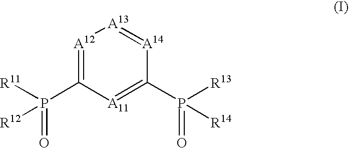

wherein R¹¹, R¹², R¹³ and R¹⁴ each independently represents a hydrogen atom or a substituent; A¹¹, A¹², A¹³ and A¹⁴ each independently represents a nitrogen atom or C—R¹⁰; and R¹⁰ represents a hydrogen atom or a substituent, and when a plurality of R¹⁰'s are present, the plurality of R¹⁰'s may be the same or different and may be connected to each other to form a ring.
(14) A compound represented by formula (II):

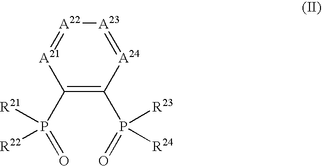

wherein R²¹, R²², R²³ and R²⁴ each independently represents a hydrogen atom or a substituent; A²¹, A²², A²³ and A²⁴ each independently represents a nitrogen atom or C—R²⁰; and R²⁰ represents a hydrogen atom or a substituent, and when a plurality of R²⁰'s are present, the plurality of R²⁰'s may be the same or different and may be connected to each other to form a ringand may be connected to each other to form a ring.

### DETAILED DESCRIPTION OF THE EXEMPLARY EMBODIMENTS

An organic electroluminescent device of the invention is characterized in that at least one kind of the phosphine oxide compounds represented by formula (I) or (II) (in the specification, this term is used in the same meaning as a “compound of the invention”) is contained in the organic compound layer. By using a compound of the invention, an organic electroluminescent device (in the specification, this term is used in the same meaning as a “device of the invention) having high light emission efficiency (e.g., external quantum efficiency) and excellent in durability can be provided. Further, by using a compound of the invention, a device capable of emission with high external quantum efficiency even in a blue region and excellent in durability can be provided.

An organic electroluminescent device according to an exemplary embodiment of the invention includes a pair of electrodes; and at least one organic compound layer between the pair of electrodes, the at least organic compound layer including a light-emitting layer, and the at least one organic compound layer contains at least one of a compound represent by formula (I) and a compound represented by formula (II)

The compound represented by formula (I) will be described in detail below.

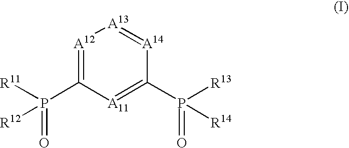

In formula (I), R¹ to R¹⁴ each independently represents a hydrogen atom or a substituent; A¹¹ to A¹⁴ each represents a nitrogen atom or C—R¹⁰; R¹⁰ represents a hydrogen atom or a substituent, and a plurality of R¹⁰'s may be the same or different and may be connected to each other to form a ring.

R¹¹ to R¹⁴ each independently represents a hydrogen atom or a substituent. R¹¹ to R¹⁴ each preferably represents a substituent, and the substituents can be arbitrarily selected from the substituent group A shown below.

### Substituent Group A:

An alkyl group (preferably having from 1 to 30 carbon atoms, more preferably from 1 to 20 carbon atoms, and especially preferably from 1 to 10 carbon atoms, e.g., methyl, ethyl, iso-propyl, tert-butyl, n-octyl, n-decyl, n-hexadecyl, cyclopropyl, cyclopentyl, cyclohexyl, etc., are exemplified), an alkenyl group (preferably having from 2 to 30 carbon atoms, more preferably from 2 to 20 carbon atoms, and especially preferably from 2 to 10 carbon atoms, e.g., vinyl, allyl, 2-butenyl, 3-pentenyl, etc., are exemplified), an alkynyl group (preferably having from 2 to 30 carbon atoms, more preferably from 2 to 20 carbon atoms, and especially preferably from 2 to 10 carbon atoms, e.g., propargyl, 3-pentynyl, etc., are exemplified), an aryl group (preferably having from 6 to 30 carbon atoms, more preferably from 6 to 20 carbon atoms, and especially preferably from 6 to 12 carbon atoms, e.g., phenyl, p-methylphenyl, naphthyl, anthranyl, etc., are exemplified), an amino group (preferably having from 0 to 30 carbon atoms, more preferably from 0 to 20 carbon atoms, and especially preferably from 0 to 10 carbon atoms, e.g., amino, methylamino, dimethylamino, diethylamino, dibenzylamino, diphenylamino, ditolylamino, etc., are exemplified), an alkoxyl group (preferably having from 1 to 30 carbon atoms, more preferably from 1 to 20 carbon atoms, and especially preferably from 1 to 10 carbon atoms, e.g., methoxy, ethoxy, butoxy, 2-ethylhexyloxy, etc., are exemplified), an aryloxy group (preferably having from 6 to 30 carbon atoms, more preferably from 6 to 20 carbon atoms, and especially preferably from 6 to 12 carbon atoms, e.g., phenyloxy, 1-naphthyloxy, 2-naphthyloxy, etc., are exemplified), a heterocyclic oxy group (preferably having from 1 to 30 carbon atoms, more preferably from 1 to 20 carbon atoms, and especially preferably from 1 to 12 carbon atoms, e.g., pyridyloxy, pyrazyloxy, pyrimidyloxy, quinolyloxy, etc., are exemplified), an acyl group (preferably having from 1 to 30 carbon atoms, more preferably from 1 to 20 carbon atoms, and especially preferably from 1 to 12 carbon atoms, e.g., acetyl, benzoyl, formyl, pivaloyl, etc., are exemplified), an alkoxycarbonyl group (preferably having from 2 to 30 carbon atoms, more preferably from 2 to 20 carbon atoms, and especially preferably from 2 to 12 carbon atoms, e.g., methoxycarbonyl, ethoxycarbonyl, etc., are exemplified), an aryloxycarbonyl group (preferably having from 7 to 30 carbon atoms, more preferably from 7 to 20 carbon atoms, and especially preferably from 7 to 12 carbon atoms, e.g., phenyloxycarbonyl, etc., are exemplified), an acyloxy group (preferably having from 2 to 30 carbon atoms, more preferably from 2 to 20 carbon atoms, and especially preferably from 2 to 10 carbon atoms, e.g., acetoxy, benzoyloxy, etc., are exemplified), an acylamino group (preferably having from 2 to 30 carbon atoms, more preferably from 2 to 20 carbon atoms, and especially preferably from 2 to 10 carbon atoms, e.g., acetylamino, benzoylamino, etc., are exemplified), an alkoxycarbonylamino group (preferably having from 2 to 30 carbon atoms, more preferably from 2 to 20 carbon atoms, and especially preferably from 2 to 12 carbon atoms, e.g., methoxycarbonylamino, etc., are exemplified), an aryloxycarbonylamino group (preferably having from 7 to 30 carbon atoms, more preferably from 7 to 20 carbon atoms, and especially preferably from 7 to 12 carbon atoms, e.g., phenyloxycarbonylamino, etc., are exemplified), a sulfonylamino group (preferably having from 1 to 30 carbon atoms, more preferably from 1 to 20 carbon atoms, and especially preferably from 1 to 12 carbon atoms, e.g., methanesulfonylamino, benzenesulfonylamino, etc., are exemplified), a sulfamoyl group (preferably having from 0 to 30 carbon atoms, more preferably from 0 to 20 carbon atoms, and especially preferably from 0 to 12 carbon atoms, e.g., sulfamoyl, methylsulfamoyl, dimethylsulfamoyl, phenylsulfamoyl, etc., are exemplified), a carbamoyl group (preferably having from 1 to 30 carbon atoms, more preferably from 1 to 20 carbon atoms, and especially preferably from 1 to 12 carbon atoms, e.g., carbamoyl, methylcarbamoyl, diethylcarbamoyl, phenylcarbamoyl, etc., are exemplified), an alkylthio group (preferably having from 1 to 30 carbon atoms, more preferably from 1 to 20 carbon atoms, and especially preferably from 1 to 12 carbon atoms, e.g., methylthio, ethylthio, etc., are exemplified), an arylthio group (preferably having from 6 to 30 carbon atoms, more preferably from 6 to 20 carbon atoms, and especially preferably from 6 to 12 carbon atoms, e.g., phenylthio, etc., are exemplified), a heterocyclic thio group (preferably having from 1 to 30 carbon atoms, more preferably from 1 to 20 carbon atoms, and especially preferably from 1 to 12 carbon atoms, e.g., pyridylthio, 2-benzimizolylthio, 2-benzoxazolylthio, 2-benzothiazolylthio, etc., are exemplified), a sulfonyl group (preferably having from 1 to 30 carbon atoms, more preferably from 1 to 20 carbon atoms, and especially preferably from 1 to 12 carbon atoms, e.g., mesyl, tosyl, etc., are exemplified), a sulfinyl group (preferably having from 1 to 30 carbon atoms, more preferably from 1 to 20 carbon atoms, and especially preferably from 1 to 12 carbon atoms, e.g., methanesulfinyl, benzenesulfinyl, etc., are exemplified), a ureido group (preferably having from 1 to 30 carbon atoms, more preferably from 1 to 20 carbon atoms, and especially preferably from 1 to 12 carbon atoms, e.g., ureido, methylureido, phenylureido, etc., are exemplified), a phosphoric amido group (preferably having from 1 to 30 carbon atoms, more preferably from 1 to 20 carbon atoms, and especially preferably from 1 to 12 carbon atoms, e.g., diethylphosphoric amido, phenylphosphoric amido, etc., are exemplified), a hydroxyl group, a mercapto group, a halogen atom (e.g., a fluorine atom, a chlorine atom, a bromine atom, an iodine atom), a cyano group, a sulfo group, a carboxyl group, a nitro group, a hydroxamic acid group, a sulfino group, a hydrazino group, an imino group, a heterocyclic group (preferably having from 1 to 30 carbon atoms, and more preferably from 1 to 12 carbon atoms, and as the hetero atoms, e.g., a nitrogen atom, an oxygen atom, a sulfur atom are exemplified, specifically, e.g., imidazolyl, pyridyl quinolyl, furyl, thienyl, piperidyl, morpholino, benzoxazolyl, benzimidazolyl, benzothiazolyl, carbazolyl, azepinyl, etc., are exemplified), a silyl group (preferably having from 3 to 40 carbon atoms, more preferably from 3 to 30 carbon atoms, and especially preferably from 3 to 24 carbon atoms, e.g., trimethylsilyl, triphenylsilyl, etc., are exemplified), a silyloxy group (preferably having from 3 to 40 carbon atoms, more preferably from 3 to 30 carbon atoms, and especially preferably from 3 to 24 carbon atoms, e.g., trimethylsilyloxy, triphenylsilyloxy, etc., are exemplified), and a phosphoryl group (e.g., a diphenylphosphoryl group, a dimethylphosphoryl group, etc.) are exemplified.

From viewpoints of chemical stability and thermo stability, as the preferred substituents represented by R¹¹ to R¹⁴, an alkyl group, an alkynyl group, an aryl group, an amino group, an alkoxy group, an aryloxy group, a heterocyclic oxy group, an alkylthio group, an arylthio group, a heterocyclic thio group, and a heterocyclic group are exemplified, and the more preferred are an alkyl group, an aryl group, an alkoxy group, an alkylthio group, and a heterocyclic group. Further, from viewpoints of good properties of charge transporting as well as chemical stability and thermo stability, the still more preferred are an alkyl group, an aryl group and a heterocyclic group, and from a viewpoint of broadening the pi electron system to the outside of the molecule to improve electron transporting properties, the most preferred are an aryl group and a heterocyclic group.

A¹¹ to A¹⁴ each represents a nitrogen atom or C—R¹⁰. R¹⁰ represents a hydrogen atom or a substituent. A plurality of R¹⁰'s may be the same or different. As the substituents represented by R¹⁰, substituent group A described above can be applied. The substituents represented by R¹⁰ can be selected in view of controlling the electric potential and charge mobility in accordance with device constitution and other materials used in combination with this compound. As the preferred substituents represented by R¹⁰, a hydrogen atom, an alkyl group, an alkenyl group, an alkynyl group, an aryl group, an amino group, an alkoxyl group, an aryloxy group, a heterocyclic oxy group, an acyl group, an alkylthio group, an arylthio group, a heterocyclic thio group, a sulfonyl group, a halogen atom, a cyano group, a heterocyclic group, a silyl group, a silyloxy group, and a phosphoryl group are exemplified, the more preferred are a hydrogen atom, an alkyl group, an alkenyl group, an aryl group, an amino group, an alkoxyl group, an aryloxy group, a heterocyclic oxy group, an alkylthio group, an arylthio group, a heterocyclic thio group, a halogen atom, a cyano group, a heterocyclic group, a silyl group, a silyloxy group, and a phosphoryl group, the still more preferred are a hydrogen atom, an alkyl group, an aryl group, an amino group, an alkoxyl group, an aryloxy group, a heterocyclic oxy group, a halogen atom, a cyano group, a heterocyclic group, a silyl group, and a phosphoryl group, and the especially preferred are a hydrogen atom, an alkyl group, an aryl group, a halogen atom, a cyano group, a heterocyclic group, a silyl group, and a phosphoryl group.

The compound represented by formula (II) will be described in detail below.

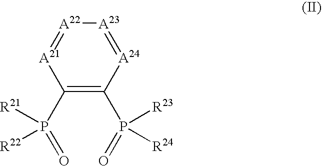

In formula (II), R²¹ to R²⁴ each independently represents a hydrogen atom or a substituent; A²¹ to A²⁴ each represents a nitrogen atom or C—R²⁰; R²⁰ represents a hydrogen atom or a substituent, and a plurality of R²⁰'s may be the same or different and may be connected to each other to form a ring.

R²¹ to R²⁴ each independently represents a hydrogen atom or a substituent. R²¹ to R²⁴ each preferably represents a substituent, and the substituents can be arbitrarily selected from substituent group A shown above.

As the preferred substituents represented by R²¹ to R²⁴, an alkyl group, an alkenyl group, an alkynyl group, an aryl group, an amino group, an alkoxy group, an aryloxy group, a heteroaryl oxy group, an alkylthio group, an arylthio group, a heteroaryl thio group, and a heterocyclic group are exemplified, the more preferred are an alkyl group, an aryl group, an alkoxy group, an alkylthio group, and a heterocyclic group, and the still more preferred are an alkyl group, an aryl group and a heterocyclic group.

A²¹ to A²⁴ each independently represents a nitrogen atom or C—R²⁰. R²⁰ represents a hydrogen atom or a substituent. A plurality of R²⁰'s may be the same or different. As the substituents represented by R²⁰, substituent group A described above can be applied. As the preferred substituents represented by R²⁰, an alkyl group, an alkenyl group, an alkynyl group, an aryl group, an amino group, an alkoxy group, an aryloxy group, a heterocyclic oxy group, an acyl group, an alkylthio group, an arylthio group, a heterocyclic thio group, a sulfonyl group, a halogen atom, a cyano group, a heterocyclic group, a silyl group, a silyloxy group, and a phosphoryl group are exemplified, the more preferred are an alkyl group, an alkenyl group, an aryl group, an amino group, an alkoxy group, an aryloxy group, a heterocyclic oxy group, an alkylthio group, an arylthio group, a heterocyclic thio group, a halogen atom, a cyano group, a heterocyclic group, a silyl group, a silyloxy group, and a phosphoryl group, the still more preferred are an alkyl group, an aryl group, an amino group, an alkoxy group, an aryloxy group, a heterocyclic oxy group, a halogen atom, a cyano group, a heterocyclic group, and a silyl group, and the still further preferred are an alkyl group, an aryl group, a halogen atom, a cyano group, a heterocyclic group, a silyl group, and a phosphoryl group.

The specific examples of the compounds represented by formula (I) and formula (II) are shown below, but the invention is not restricted to these compounds.

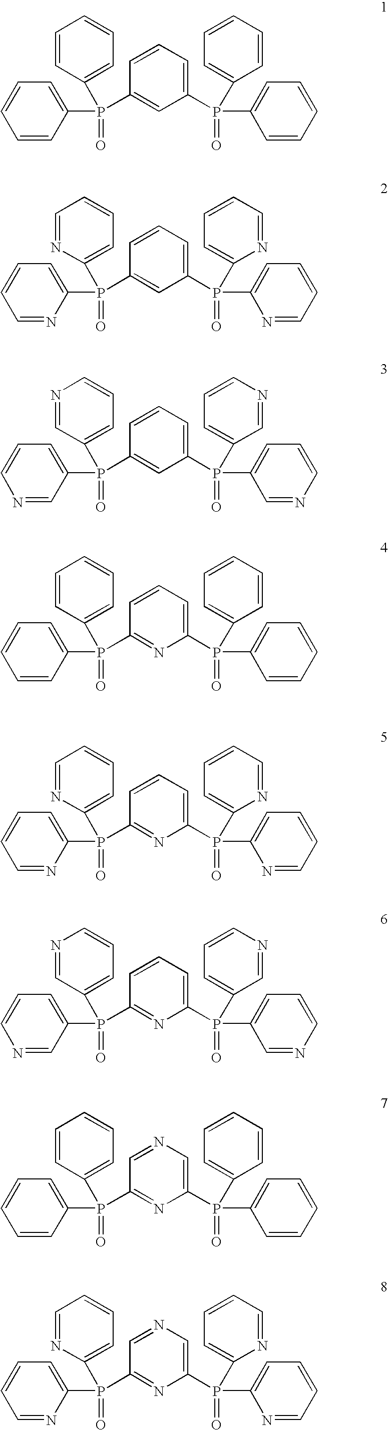

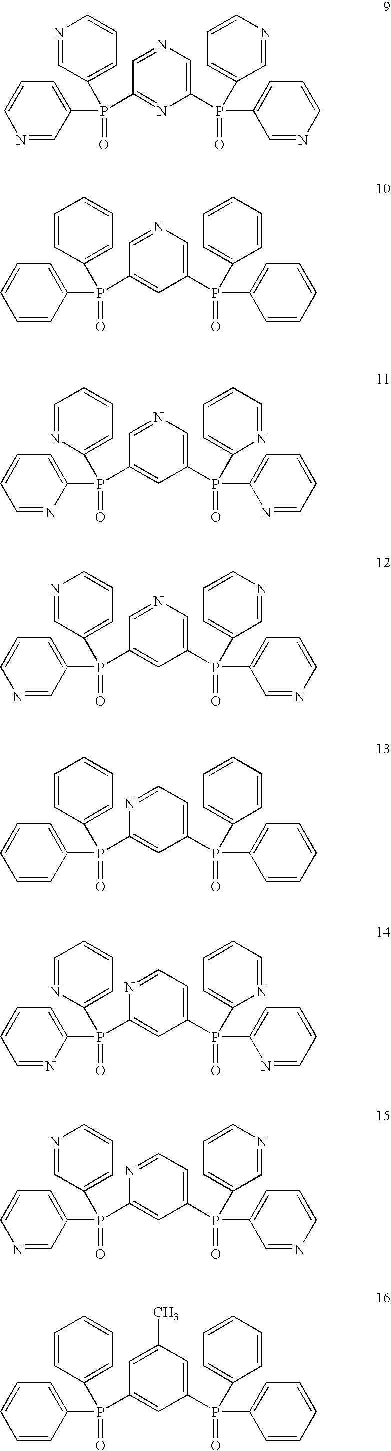

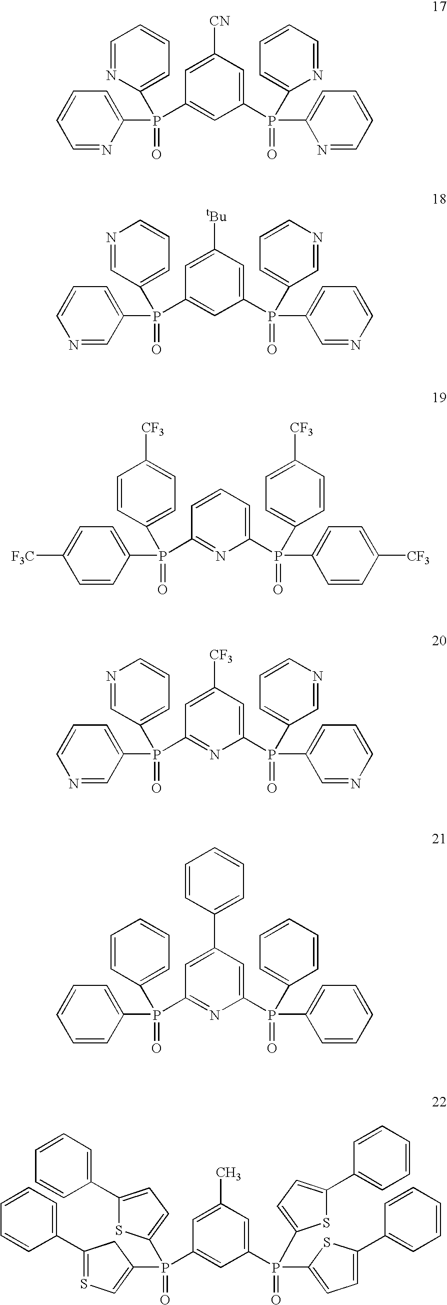

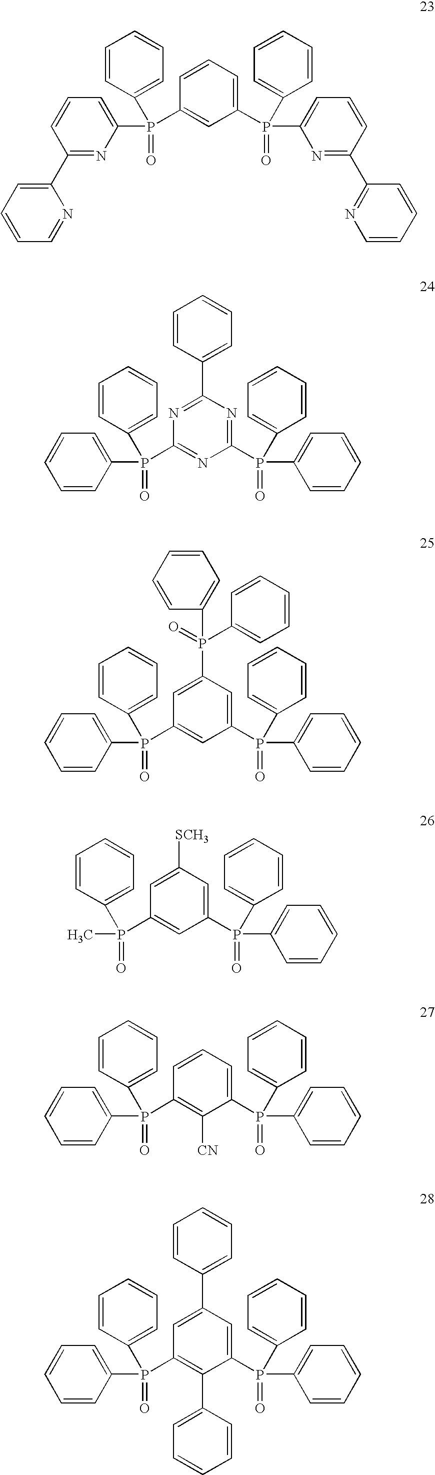

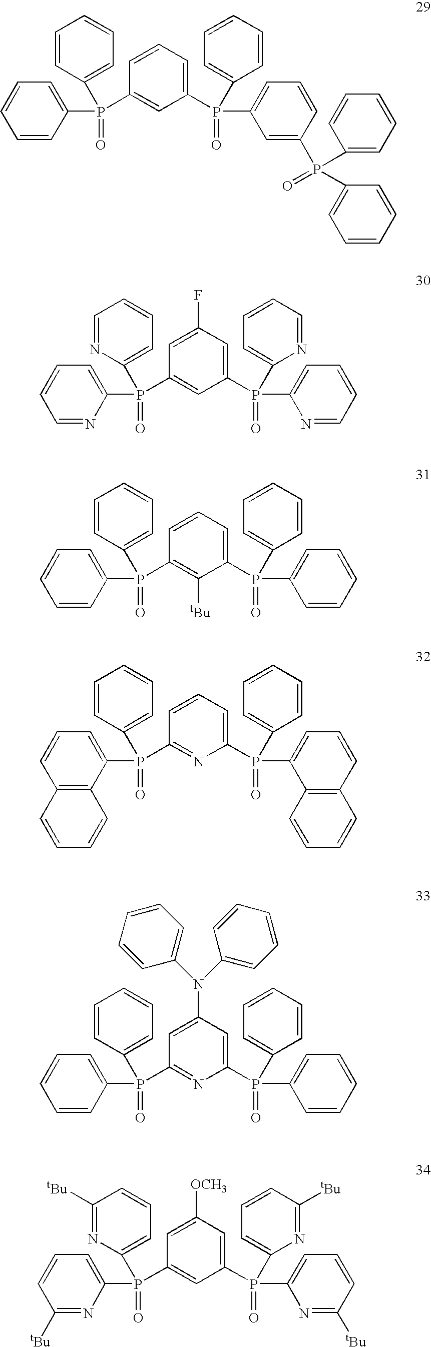

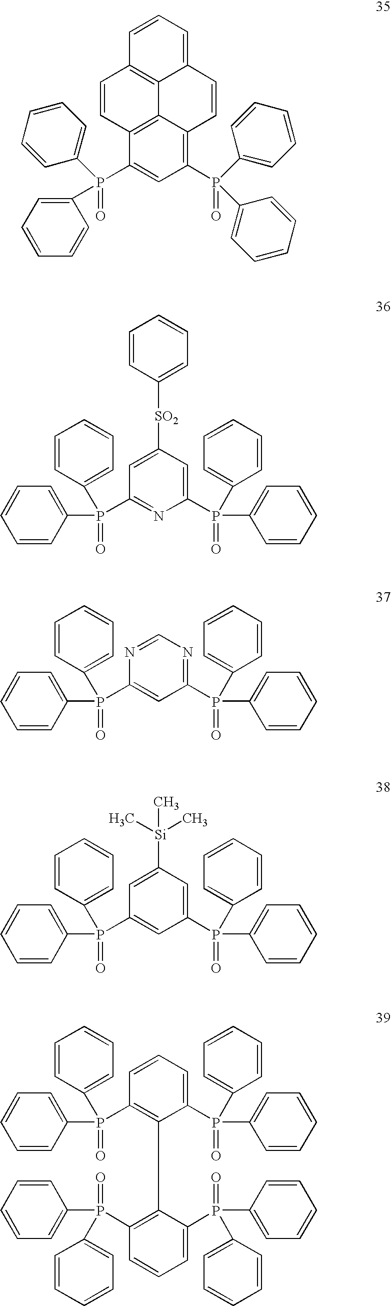

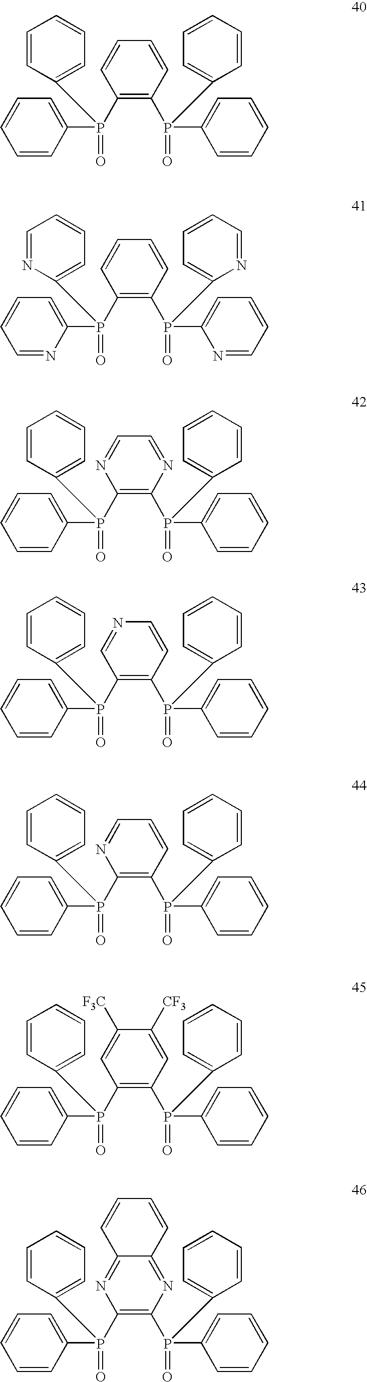

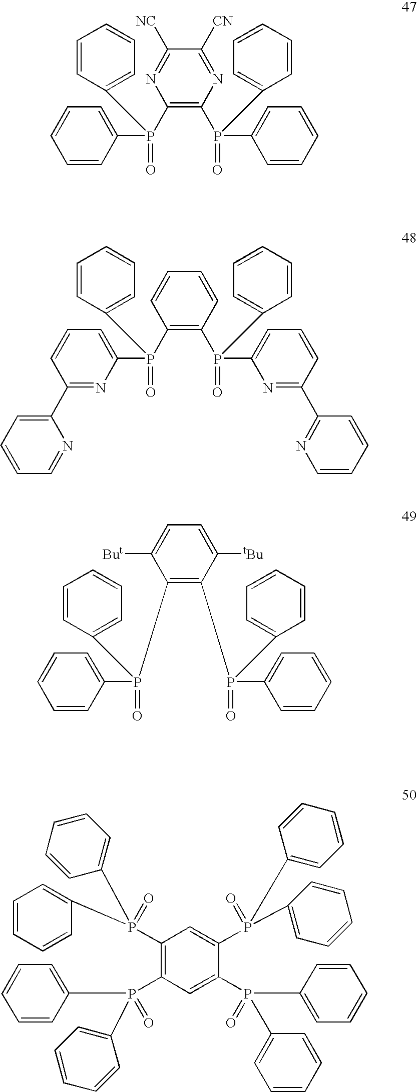

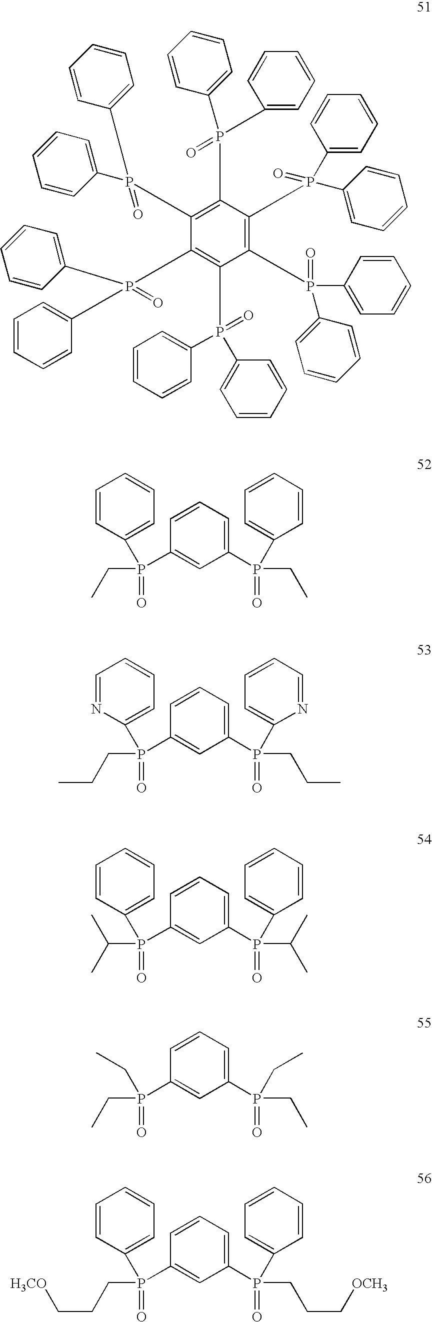

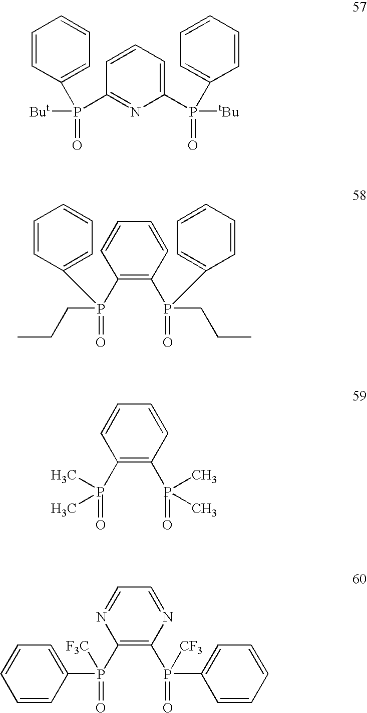

A compound represented by formula (I) or (II) can be synthesized according to various known methods. Some examples of synthesis routes are shown in the following scheme (1) and (2). In scheme (1), X represents a halogen atom; A represents C—R (R represents a hydrogen atom or a substituent) or an N atom; and M represents a metal. In the method of scheme (1), SM1 is metallized with a metallizing agent (e.g., alkyl lithium, an alkyl Grignard reagent, or a simple substance of metal, preferably alkyl lithium, and more preferably n-butyl lithium) in a solvent (e.g., an ether solvent or a hydrocarbon solvent, preferably tetrahydrofuran or diethyl ether) on a temperature condition of from −90 to 30° C., and intermediate 1 is obtained by the action of a phosphine chloride reagent (e.g., diarylchlorophosphine, dialkylchlorophosphine or alkylarylchlorophosphine is used properly according to purpose) on the metallized SM1. Intermediate 2 can be synthesized by repeating metallization and phosphination. Further, target material 1 can be synthesized by oxidation with an oxidant (e.g., mCPBA, peroxide such as hydrogen peroxide) in a solvent (e.g., a halogen solvent, preferably dichloromethane) on a temperature condition of from −30 to 80° C. When it is possible to dimetallize SM1, target material 1 can also be synthesized without going through intermediate 2 by the action of phosphinyl chloride in place of phosphine chloride. In the method of scheme (2), intermediate 2 can be synthesized by the reaction of SM1 with a phosphine reagent (e.g., diarylphosphine, dialkylphosphine or alkylarylphosphine is used properly according to purpose) in a solvent (e.g., an amide solvent, a sulfoxide solvent, a hydrocarbon solvent, an alcohol solvent, an ether solvent, a nitrile solvent, an ester solvent, a halogen solvent, or a ketone solvent, preferably an amide solvent) in the presence of a Pd catalyst (e.g., palladium acetate), and a base (e.g., potassium acetate, potassium phosphate, potassium carbonate, sodium carbonate, sodium hydrogencarbonate, rubidium carbonate or cesium carbonate, preferably potassium acetate) on a temperature condition of from 20 to 200° C. Similar to the case of scheme (1), the objective substance can be synthesized by oxidation reaction. Specifically, the method disclosed in Organic Letters 2006, Vol. 8, No. 19, 4211-4214 can be applied.

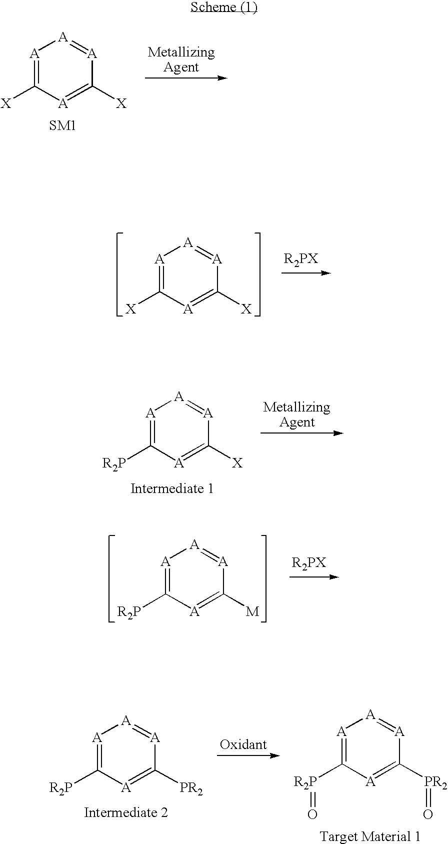

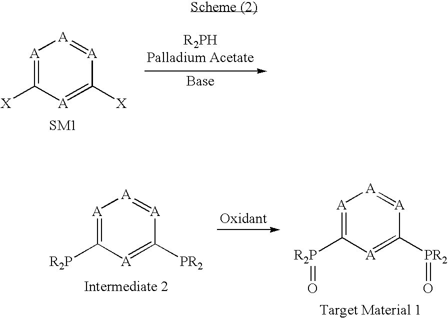

The synthesized compound can be purified according to known methods (refer to Bunri Seisei Gijutsu Handbook (Separation Purification Technique Handbook), compiled by The Chemical Society of Japan (1993), Kagaku Henkan-Ho ni Yoru Biryo Seibun Oyobi Nan-Seisei Busshitsu no Kodo Bunri (High Techniques of Separation of Micro Components and Hardly Purified Materials by Chemical Conversion Methods), IPC (1988), and Course of Experimental Chemistry, 4^{th} Edition, compiled by The Chemical Society of Japan (1990)). Specifically, extraction, adsorption, occlusion, recrystallization, reprecipitation, distillation, sublimation, ion exchange, filtration, a zone melting method, electrophoresis, centrifugation, sedimentation, washing, various kinds of chromatography, etc., are exemplified as the methods of purification.

Considering the durability of the device, the glass transition temperature (Tg) of the compound of the invention is preferably 130° C. or more and 450° C. or less, more preferably 135° C. or more and 450° C. or less, still more preferably 140° C. or more and 450° C. or less, especially preferably 150° C. or more and 450° C. or less, and most preferably 160° C. or more and 450° C. or less.

Tg can be confirmed by calorimetry such as differential scanning calorimetry (DSC) and differential thermal analysis (DTA), and X-ray diffraction (XRD) and observation with a polarizing microscope.

### (Organic Electroluminescent Device)

A device of the invention will be described in detail below.

A light-emitting device in the invention includes a substrate having thereon a cathode and an anode, and an organic compound layer between the electrodes, the organic layer including an organic electroluminescent layer (light-emitting layer). The organic compound layer may be layers containing an organic compound alone, or may be layers containing an inorganic compound in addition to the organic compound. Accordingly, an organic layer in the invention may be the constitution including a light-emitting layer alone. From the properties of the light-emitting device, it is preferred that at least one electrode of the cathode and anode is transparent.

A light-emitting device of the invention has at least one organic electroluminescent layer (light-emitting layer) as the organic compound layer. Further, as organic compound layers other than the light-emitting layer, a hole injecting layer, a hole transporting layer, an electron blocking layer, an exciton blocking layer, a hole blocking layer, an electron transporting layer, an electron injecting layer, and a protective layer may be arbitrarily arranged, and each layer may unite functions of other layers. Further, each layer may comprise a plurality of secondary layers.

Constituents of a light-emitting device of the invention are described in detail below.

### (Substrate)

A substrate for use in the invention is preferably a substrate that does not scatter or attenuate the light emitted from the organic layer. The specific examples of the materials of the substrate include inorganic materials, e.g., yttria stabilized zirconia (YSZ), glass, etc., and organic materials, such as polyester, e.g., polyethylene terephthalate, polybutylene phthalate, polyethylene naphthalate, etc., polystyrene, polycarbonate, polyether sulfone, polyallylate, polyimide, polycycloolefin, norbornene resin, poly(chloro-trifluoroethylene), etc.

When glass is used as a substrate, non-alkali glass is preferably used as the material for reducing elution of ions from the glass. Further, when soda lime glass is used, it is preferred to provide a barrier coat such as silica. In the case of organic materials, materials excellent in heat resistance, dimensional stability, solvent resistance, electrical insulating properties and processability are preferably used.

The form, structure and size of a substrate are not especially restricted, and these can be arbitrarily selected in accordance with the intended use and purpose of the light-emitting device. In general, a substrate is preferably in a plate-like form. The structure of a substrate may be a single layer structure or may be a layered structure, and may consist of a single member or may be formed of two or more members.

A substrate may be colorless and transparent, or may be colored and transparent, but from the point of not scattering or attenuating the light emitted from the light-emitting layer, a colorless and transparent substrate is preferably used.

A substrate can be provided with a moisture permeation preventing layer (a gas barrier layer) on the front surface or rear surface.

As the materials of the moisture permeation preventing layer (the gas barrier layer), inorganic materials such as silicon nitride and silicon oxide are preferably used. The moisture permeation preventing layer (the gas barrier layer) can be formed, for example, by a high frequency sputtering method.

When a thermoplastic substrate is used, if necessary, a hard coat layer and an undercoat layer may further be provided.

### (Anode)

An anode is generally sufficient to have the function of the electrode to supply holes to an organic layer. The form, structure and size of an anode are not especially restricted, and these can be arbitrarily selected from known materials of electrode in accordance with the intended use and purpose of the light-emitting device. As described above, an anode is generally provided as a transparent anode.

As the materials of anode, for example, metals, alloys, metal oxides, electrically conductive compounds, and mixtures of these materials are preferably exemplified. The specific examples of the materials of anode include electrically conductive metal oxides, e.g., tin oxide doped with antimony or fluorine (ATO, FTO), tin oxide, zinc oxide, indium oxide, indium tin oxide (ITO), indium zinc oxide (IZO), etc., metals, e.g., gold, silver, chromium, nickel, etc., mixtures or layered products of these metals with electrically conductive metal oxides, inorganic electrically conductive substances, e.g., copper iodide, copper sulfide, etc., organic electrically conductive materials, e.g., polyaniline, polythiophene, polypyrrole, etc., layered products of these materials with ITO, etc. Of these materials, electrically conductive metal oxides are preferred, and ITO is especially preferred in view of productivity, high conductivity, transparency and the like.

An anode can be formed on the substrate in accordance with various methods arbitrarily selected from, for example, wet methods, e.g., a printing method, a coating method, etc., physical methods, e.g., a vacuum deposition method, a sputtering method, an ion plating method, etc., and chemical methods, e.g., a CVD method, a plasma CVD method, etc., taking the suitability with the material to be used in the anode into consideration. For example, in the case of selecting ITO as the material of an anode, the anode can be formed according to a direct current or high frequency sputtering method, a vacuum deposition method, an ion plating method, etc.

In an organic electroluminescent device of the invention, the position of the anode to be formed is not especially restricted and can be formed anywhere. The position can be arbitrarily selected in accordance with the intended use and purpose of the light-emitting device, but preferably provided on the substrate. In this case, the anode may be formed on the entire surface of one side of the substrate, or may be formed on a part of the organic layer.

As patterning in forming an anode, patterning may be performed by chemical etching such as by photo-lithography, may be carried out by physical etching such as by laser, may be performed by vacuum deposition or sputtering on a superposed mask, or a lift-off method and a printing method may be used.

The thickness of an anode can be optionally selected in accordance with the materials of the anode, so that cannot be regulated unconditionally, but the thickness is generally from 10 nm to 50 μm or so, and is preferably from 50 nm to 20 μm.

The value of resistance of an anode is preferably 10³Ω/□ or less, and more preferably 10²Ω/□ or less. In the case where an anode is transparent, the anode may be colorless and transparent, or colored and transparent. For the coupling out of luminescence from the transparent anode side, the transmittance is preferably 60% or more, and more preferably 70% or more.

In connection with transparent anodes, description is found in Yutaka Sawada supervised, Tomei Doden-Maku no Shintenkai (New Development in Transparent Conductive Films), CMC Publishing Co., Ltd. (1999), and the description therein can be referred to. In the case of using a plastic substrate low in heat resistance, a transparent anode film-formed with ITO or IZO at a low temperature of 150° C. or less is preferred.

### (Cathode)

A cathode is generally sufficient to have the function of the electrode to supply electrons to an organic layer. The form, structure and size of a cathode are not especially restricted, and these can be arbitrarily selected from known materials of electrode in accordance with the intended use and purpose of the light-emitting device.

As the materials of cathode, for example, metals, alloys, metal oxides, electrically conductive compounds, and mixtures of these materials are exemplified. The specific examples of the materials of cathode include alkali metals (e.g., Li, Na, K, Cs, etc.), alkaline earth metals (e.g., Mg, Ca, etc.), gold, silver, lead, aluminum, sodium-potassium alloy, lithium-aluminum alloy, magnesium-silver alloy, indium, rare earth metals, e.g., ytterbium, etc. These materials may be used by one kind alone, but from the viewpoint of the compatibility of stability and an electron injecting property, two or more kinds of materials are preferably used in combination.

As the materials constituting a cathode, alkali metals and alkaline earth metals are preferred of these materials in the point of electron injection, and materials mainly including aluminum are preferred for their excellent preservation stability.

The materials mainly including aluminum mean aluminum alone, alloys of aluminum with 0.01 to 10 mass % of alkali metal or alkaline earth metal, or mixtures of these (e.g., lithium-aluminum alloy, magnesium-aluminum alloy, etc.).

The materials of cathode are disclosed in JP-A-2-15595 and JP-A-5-121172, and the materials described in these patents can also be used in the invention.

A cathode can be formed by known methods with no particular restriction. For example, a cathode can be formed according to wet methods, e.g., a printing method, a coating method, etc., physical methods, e.g., a vacuum deposition method, a sputtering method, an ion plating method, etc., and chemical methods, e.g., a CVD method, a plasma CVD method, etc., taking the suitability with the material constituting the cathode into consideration. For example, in the case of selecting metals as the material of a cathode, the cathode can be formed with one or two or more kinds of materials at the same time or in order by sputtering, etc.

As patterning in forming a cathode, patterning may be performed by chemical etching such as by photo-lithography, may be carried out by physical etching such as by laser, may be performed by vacuum deposition or sputtering on a superposed mask, or a lift-off method and a printing method may be used.

The position of the cathode to be formed is not especially restricted and can be formed anywhere in the invention. The cathode may be formed on the entire surface of the organic layer, or may be formed on a part of the organic layer.

A dielectric layer including fluoride or oxide of alkali metal or alkaline earth metal may be inserted between the cathode and the organic layer in a thickness of from 0.1 to 5 nm. The dielectric layer can be regarded as one kind of an electron injecting layer. The dielectric layer can be formed, for example, according to a vacuum deposition method, a sputtering method, an ion plating method, etc.

The thickness of a cathode can be optionally selected in accordance with the materials of the cathode, so that cannot be regulated unconditionally, but the thickness is generally from 10 nm to 5 μm or so, and is preferably from 50 nm to 1 μm.

A cathode may be transparent or opaque. A transparent cathode can be formed by forming a thin film of the materials of the cathode in a thickness of from 1 to 10 nm, and further stacking transparent conductive materials such as ITO and IZO.

### (Organic Compound Layer)

An organic compound layer of the invention will be described in detail below.

An organic electroluminescent device of the invention includes at least one organic compound layer between a pair of electrodes, the at least one organic compound layer including a light-emitting layer. As other organic compound layers other than the organic electroluminescent layer, a hole transporting layer, an electron transporting layer, a charge blocking layer, a hole injecting layer and an electron injecting layer are exemplified, as mentioned above.

### (Forming of Organic Compound Layer)

Each layer constituting organic layers can be preferably formed by any of dry film-forming methods such as a vacuum deposition method, a sputtering method, etc., a transfer method, and a printing method.

### (Organic Electroluminescent Layer)

The organic electroluminescent layer is a layer having functions to receive, when an electric field is impressed, holes from the anode, hole injecting layer or hole transporting layer, and electrons from the cathode, electron injecting layer or electron transporting layer, and to offer the field of recombination of holes and electrons to emit light.

An organic electroluminescent device of the invention may be a device using emission from the singlet excited state (fluorescence) or may be a device using emission from the triplet excited state (phosphorescence), but from the viewpoint of emission efficiency, a device using phosphorescence is preferred.

A light-emitting layer in the invention may consist of light-emitting materials alone, or may comprise a mixed layer of a host material and a light-emitting material.

A light-emitting layer may include one layer alone or two or more layers, and in the case of two or more layers, each layer may emit light of color different from other layers.

When an organic electroluminescent device of the invention is a device using phosphorescence, it is preferred that the light-emitting layer should consist of at least one kind of phosphorescent material and at least one kind of host material. Here, the host material means a material other than the light-emitting material of the materials constituting the light-emitting layer, and having at least one function of a function of dispersing a light-emitting material and maintaining the dispersion in the light-emitting layer, a function of receiving holes from an anode and a hole transporting layer, a function of receiving electrons from a cathode and an electron transporting layer, a function of transporting at least one of holes and electrons, a function of offering the place of recombination of holes and electrons, a function of transporting the energy of exciton generated by recombination to the light-emitting material, and a function of transporting at least one of holes and electrons to the light-emitting material.

The host material is preferably a charge transporting material. One or two or more host materials may be used. For example, the constitution of the mixture of an electron transporting host material and a hole transporting host material is exemplified. Further, a material not having a charge transporting property and not emitting light may be contained in the light-emitting layer.

As the host materials contained in a light-emitting layer of the invention, in addition to compounds of the invention, materials having a carbazole skeleton, materials having a diarylamine skeleton, materials having a pyridine skeleton, materials having a pyrazine skeleton, materials having triazine skeleton, materials having arylsilane skeleton, and materials exemplified as those used in a hole injecting layer, a hole transporting layer, an electron injecting layer and an electron transporting layer as described later, are exemplified.

A compound represented by formula (I) and a compound represented by formula (II) may be contained in any layer of the organic compound layers and may be contained in two or more layers, but is preferably contained in a light-emitting layer, a hole blocking layer, an electron transporting layer, or an electron injecting layer, and most preferably contained in a light-emitting layer as a host material.

The content of the compound in an electron injecting layer is preferably from 70 to 99.9 mass % (weight %), and more preferably from 90 to 99 mass %. The content of the compound in a light-emitting layer is preferably from 50 to 99.9 mass %, and more preferably from 60 to 99 mass %.

When a device of the invention is a light-emitting device utilizing phosphorescence, the lowest triplet excited level (T₁ level) of the compound is preferably 65 kcal/mol (272.35 kJ/mol) or more and 95 kcal/mol (398.05 kJ/mol) or less, more preferably 67 kcal/mol (280.73 kJ/mol) or more and 95 kcal/mol (398.05 kJ/mol) or less, and still more preferably 69 kcal/mol (289.11 kJ/mol) or more and 95 kcal/mol (398.05 kJ/mol) or less.

T₁ level can be estimated from the short wavelength edge of the phosphorescence spectrum.

### (Light-Emitting Material)

As light-emitting materials of the invention, any of a phosphorescent material, a fluorescent material, etc. can be used.

A light-emitting layer of the invention may contain two or more light-emitting layer to improve color purity or to expand the range of light-emitting wavelength.

### (Fluorescent Material)

The examples of fluorescent materials generally include various metal complexes represented by metal complexes of benzoxazole, benzimidazole, benzothiazole, styrylbenzene, polyphenyl, diphenylbutadiene, tetraphenylbutadiene, naphthalimide, coumarin, pyrane, perinone, oxadiazole, aldazine, pyraridine, cyclopentadiene, bisstyrylanthracene, quinacridone, pyrrolopyridine, thiadiazolopyridine, styrlamine, condensed aromatic compounds (e.g., anthracene, phenanthroline, pyrene, perylene, rubrene, and pentacene), and 8-quinolinol, pyrromethene complexes, and rare earth complexes; polymer compounds such as polythiophene, polyphenylene, polyphenylenevinylene; organic silane; and derivatives thereof

### (Phosphorescent Material)

The examples of phosphorescent materials generally include complexes containing a transition metal atom or a lanthanoid atom.

The transition metal atoms are not especially restricted, but ruthenium, rhodium, palladium, tungsten, rhenium, osmium, iridium, gold, silver, copper, and platinum are preferably exemplified; rhenium, iridium and platinum are more preferred, and iridium and platinum are still more preferred.

As lanthanoid atoms, lanthanum, cerium, praseodymium, neodymium, samarium, europium, gadolinium, terbium, dysprosium, holmium, erbium, thulium, ytterbium, and lutecium are exemplified. Of these lanthanoid atoms, neodymium, europium and gadolinium are preferred.

As the examples of ligands of complexes, the ligands described, for example, in G. Wilkinson et al., Comprehensive Coordination Chemistry, Pergamon Press (1987), H. Yersin, Photochemistry and Photophysics of Coordination Compounds, Springer-Verlag (1987), and Akio Yamamoto, Yuki Kinzoku Kagaku-Kiso to Oyo-(Organic Metal Chemistry—Elements and Applications), Shokabo Publishing Co. (1982) are exemplified.

Specific examples of the ligand include a halogen ligand (preferably, a chlorine ligand), an aromatic hydrocarbon ring ligand (containing preferably from 5 to 30 carbon atoms, more preferably from 6 to 30 carbon atoms, still more preferably from 6 to 20 carbon atoms, particularly preferably from 6 to 12 carbon atoms; e.g., cyclopentadienyl anion, benzene anion, or naphthyl anion), a nitrogen-containing heterocyclic ligand (containing preferably from 5 to 30 carbon atoms, more preferably from 6 to 30 carbon atoms, still more preferably from 6 to 20 carbon atoms, particularly preferably from 6 to 12 carbon atoms; e.g., phenylpyridine, benzoquinoline, quinolinol, bipyridyl or phenanthroline), a diketone ligand (e.g., acetylacetone), a carboxylic acid ligand (containing preferably from 2 to 30 carbon atoms, more preferably from 2 to 20 carbon atoms, still more preferably from 2 to 16 carbon atoms; e.g., acetic acid ligand), an alcoholate ligand (containing preferably from 1 to 30 carbon atoms, more preferably from 1 to 20 carbon atoms, still more preferably from 6 to 20 carbon atoms; e.g., phenolate ligand), a silyloxy ligand (containing preferably from 3 to 40 carbon atoms, more preferably from 3 to 30 carbon atoms, still more preferably from 3 to 20 carbon atoms; e.g., trimethylsilyloxy ligand, dimethyl-tert-buthylsilyloxy ligand, or triphenylsilyloxy ligand), a carbon monoxide ligand, an isonitrile ligand, a cyano ligand, a phosphorus ligand (containing preferably from 3 to 40 carbon atoms, more preferably from 3 to 30 carbon atoms, still more preferably from 3 to 20 carbon atoms, particularly preferably from 6 to 20 carbon atoms; e.g., triphenylphosphine ligand), a thiolate ligand (containing preferably from 1 to 30 carbon atoms, more preferably from 1 to 20 carbon atoms, still more preferably from 6 to 20 carbon atoms; e.g., phenylthiolate ligand), and a phosphine oxide ligand (containing preferably from 3 to 30 carbon atoms, more preferably from 8 to 30 carbon atoms, still more preferably from 18 to 30 carbon atoms; e.g., triphenylphosphine oxide ligand). The nitrogen-containing heterocyclic ligands are more preferred.

The complex may have one transition metal atom in the compound, or may be a so-called polynuclear complex having two or more transition metal atoms, or may simultaneously contain different kinds of metal atoms.

Of these, phosphorescent compounds described in patents, for example, U.S. Pat. No. 6,303,238 B1, U.S. Pat. No. 6,097,147, WO 00/57676, WO 00/70655, WO 01/08230, WO 01/39234 A2, WO 01/41512 A1, WO 02/02714 A2, WO 02/15645 A1, WO 02/44189 A1, WO 05/19373 A2, JP-A-2001-247859, JP-A-2002-302671, JP-A-2002-117978, JP-A-2003-133074, JP-A-2002-235076, JP-A-2003-123982, JP-A-2002-170684, EP1211257, JP-A-2002-226495, JP-A-2002-234894, JP-A-2001-247859, JP-A-2001-298470, JP-A-2002-173674, JP-A-2002-203678, JP-A-2002-203679, JP-A-2004-357791, JP-A-2006-256999, JP-A-2007-19462, JP-A-2007-84635, and JP-A-2007-96259 are illustrated as specific examples of the light-emitting material. Examples of still more preferred light-emitting materials include complexes of Ir, Pt, Cu, Re, W, Rh, Ru, Pd, Os, Eu, Tb, Gd, Dy, and Ce. Ir, Pt and Re complexes are particularly preferred, and Ir, Pt and Re complexes having at least one coordination mode such as metal-carbon bond, metal-nitrogen bond, metal-oxygen bond, and metal sulfur bond are preferred among them. Further, in view of luminance efficiency, driving durability, and chromaticity, Ir complexes, Pt complexes, and Re complexes containing polydentate ligands having three or more coordination sites are particularly preferred, with Ir complexes and Pt complexes being most preferred. Of them, Pt complexes having a tetradentate ligand (quadridentate ligand) are particularly preferred.

Light-emitting materials are not particularly limited, but use of a phosphorescent material is preferred. Use of a phosphorescent material of an iridium complex or a platinum complex is more preferred, and use of a phosphorescent material having a tetradentate ligand is particularly preferred. However, other phosphorescent materials may be used together with them.

As the complex phosphorescent materials, there can be illustrated compounds described in Coordination Chemistry Reviews 250 (2006), 2093-2126.

As the iridium complex phosphorescent materials, there can be illustrated compounds described in WO 00/70655, WO 01/41512, WO 02/5645, JP-A-2002-117978, WO 04/085450, WO 06/121811, WO 05/019373, and WO 05/113704.

The specific examples of the platinum complex phosphorescent material having a tetradentate ligand include compounds disclosed in WO 2004/108857.

As the platinum complex phosphorescent material having a tetradentate ligand, more specifically, preferred are compounds described in U.S. Pat. No. 6,653,654, WO 2004/099339, WO 2004/108857, JP-A-2005-310733, JP-A-2005-317516, JP-A-2006-261623, JP-A-2006-93542, JP-A-2006-256999, WO 2006/098505, JP-A-2007-19462, JP-A-2007-96255, JP-A-2007-96259, WO 2005/042444, JP-A-2006-232784, US 2006/0134461, and WO 2005/042550.

As a phosphorescent material of the invention, preferred is a platinum complex represented by formula (C-1).

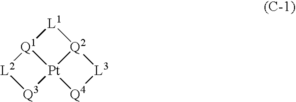

wherein Q¹, Q², Q³ and Q⁴ each independently represents a group coordinating to Pt; and L¹, L² and L³ each independently represents a single bond or a divalent linking group.

The formula (C-1) will be described. Q¹, Q², Q³ and Q⁴ each independently represents a group coordinating to Pt. As the bond between each of Q¹, Q², Q³ and Q⁴ and Pt, any bond such as a covalent bond, an ionic bond, a coordinate bond can be adopted. As atoms in Q¹, Q², Q³ and Q⁴ bonding to Pt, a carbon atom, a nitrogen atom, an oxygen atom, a sulfur atom, a phosphorus atom are preferred, and at least one of atoms in Q¹, Q², Q³ and Q⁴ bonding to Pt is preferably a carbon atom, and more preferable two atoms are carbon atoms.

As Q¹, Q², Q³ and Q⁴ bonding to Pt via a carbon atom, an anionic ligand or nonionic ligand may be used. As the anionic ligand, a vinyl ligand, an aromatic hydrocarbon cyclic ligand (for example, a benzene ligand, a naphthalene ligand, an anthracene ligand, a phenanthrene ligand), a heterocyclic ligand (for example, a fran ligand, a thiophene ligand, a pyridine ligand, a pyrazine ligand, a pyrimidine ligand, a pyridazine ligand, a triazine ligand, a thiazol ligand, an oxazole ligand, a pyrrole ligand, an imidazole ligand, a pyrazole ligand, a triazole ligand and a condensed group thereof (such as a quinoline ligand, a benzothiazole ligand) are exemplified. As the nonionic ligand, a carbene ligand is exemplified.

As Q¹, Q², Q³ and Q⁴ bonding to Pt via a nitrogen atom, a nonionic ligand or anionic ligand may be used. As the nonionic ligand, a nitrogen-containing heterocyclic ligand (a pyridine ligand, a pyrazine ligand, a pyrimidine ligand, a pyridazine ligand, a triazine ligand, an imidazole ligand, a pyrazole ligand, a triazole ligand, an oxazole ligand, a thiazole ligand and a condensed group thereof (such as a quinoline ligand, a benzimidazole ligand)), an amine ligand, a nitrile ligand, an imine ligand are exemplified. As the anionic ligand, an amino ligand, an imino ligand, a nitrogen atom-containing heterorocyclic ligand (a pyrrole ligand, an imidazole ligand, a triazole ligand and a condensed group thereof (such as an indole ligand, a benzimidazole ligand)) are exemplified.

As Q¹, Q², Q³ and Q⁴ bonding to Pt via an oxygen atom, a nonionic ligand or anionic ligand may be used. As the nonionic ligand, an ether ligand, a ketone ligand, an ester ligand, an amide ligand, an oxygen-containing heterocyclic ligand (a fran ligand, an oxazole ligand and a condensed group thereof (such as a benzoxazole ligand)) are exemplified. As the anionic ligand, an alkoxy ligand, an aryloxy ligand, a heteroaryloxy ligand, an acyloxy ligand and a silyloxy ligand are exemplified.

As Q¹, Q², Q³ and Q⁴ bonding to Pt via a sulfur atom, a nonionic ligand or anionic ligand may be used. As the nonionic ligand, a thioether ligand, a thioketone ligand, a thioester ligand, a thioamide ligand, a sulfur-containing heterocyclic ligand (a thiophene ligand, a thiazol ligand and a condensed group thereof (such as a benzothiazole ligand)) are exemplified. As the anionic ligand, an alkylmercapto ligand, an arylmercapto ligand, a heteroarylmercapto ligand are exemplified.

As Q¹, Q², Q³ and Q⁴ bonding to Pt via a phosphorous atom, a nonionic ligand or anionic ligand may be used. As the nonionic ligand, a phosphine ligand, a phosphoric acid ester ligand, a phosphorous acid ester ligand, and a phosphorous-containing heterocyclic ligand (a phosphinine ligand) are exemplified. As the anionic ligand, a phosphino ligand, a phosphinyl ligand, and a phosphoryl ligand are exemplified.

Groups represented by Q¹, Q², Q³ and Q⁴ may have a substituent. As the substituent, those of the substituent group A can be appropriately exemplified. Further, substituents may be connected to each other (When Q³ and Q⁴ are connected, the compound represented by formula (C-1) is a platinum complex having a cyclic tetradentate ligand).

As the groups represented by Q¹, Q², Q³ and Q⁴, preferred are an aromatic hydrocarbon cyclic ligand bonding to Pt via a carbon atom, an aromatic heterocyclic ligand bonding to Pt via a carbon atom, a nitrogen-containing aromatic heterocyclic ligand bonding to Pt via a nitrogen atom, an acyloxy ligand, an alkyloxy ligand, an aryloxy ligand, a heteroaryloxy ligand, and a silyloxy ligand; more preferred are an aromatic hydrocarbon cyclic ligand bonding to Pt via a carbon atom, an aromatic heterocyclic ligand bonding to Pt via a carbon atom, a nitrogen-containing aromatic heterocyclic ligand bonding to Pt via a nitrogen atom, an acyloxy ligand, and an aryloxy ligand; and still more preferred are an aromatic hydrocarbon cyclic ligand bonding to Pt via a carbon atom, an aromatic heterocyclic ligand bonding to Pt via a carbon atom, a nitrogen-containing aromatic heterocyclic ligand bonding to Pt via a nitrogen atom, and an acyloxy ligand.

L¹, L², and L³ each independently represent a single bond or a divalent linking group. As the divalent linking group represented by L¹, L², and L³, an alkylene group (methylene, ethylene, propylene), an arylene group (phenylene, naphthalendiyl), a heteroarylene group (pyridinediyl, thiophenediyl), an imino group (—NR—) (phenylimino group), an oxy group (—O—), a thio group (—S—), a phosphinidene (—PR—) (phenyl phosphinidene), silylene group (—SiRR′—) (dimethyl silylene group, diphenyl silylene group), and combination thereof are exemplified. These linking groups may have a substituent.

As L¹, L², and L³, preferred are a single bond, an alkylene group, an arylene group, an heteroarylene group, an imino group, a oxy group, a thio group, and a silylene group; more preferred are a single bond, an alkylene group, an arylene group, and an imino group; still more preferred are a single bond, an alkylene basis, and an arylene group, and still more preferred a single bond, a methylene group, a phenylene group; and still more preferred are a single bond and a di-substituted methylene group; and still more preferred are a single bond, a dimethylmethylene group, a diethylmethylene group, a diisobutylstyrene group, a dibenzylmethylene group, an ethylmethylmethylene group, a methylpropylmethylene group, an isobutylmethylmethylene group, a diphenylmethylene group, a methylphenylmethylene group, a cyclohexandiyl group, a cyclopentadiyl group, a fluorernediyl group, and a fluoromethylmethylene group; most preferred are a single bond, a dimethylmethylene group, a diphenylmethylene group and a chrolohexandiyl group.

As the platinum complex having a tetradentate ligand, represented by formula (C-1), one of preferred compound is a platinum complex represented by formula (A).

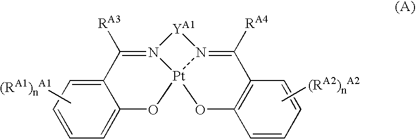

In formula (A), R^{A3} and R^{A4} each independently represents a hydrogen atom or a substituent; R^{A1} and R^{A2} each independently represents a substituent, and when a plurality of R^{A1} and R^{A2} are present, the plurality of R^{A1} and R^{A2} may be the same or different, and R^{A1} and R^{A2} may be linked to each other to form a ring; n^{A1} and n^{A2} each independently represents an integer of from 0 to 4; and Y^{A1} represents a linking group

As substituents represented by R^{A1}, R^{A2}, R^{A3} and R^{A4}, any substituent can be selected from the substituent group A above.

As the linking group represented by Y^{A1}, those exemplified as the linking group represented by L¹, L² and L³ are exemplified.

As substituents represented by R^{A1}, R^{A2}, R^{A3}, and R^{A4}, an alkyl group, an aryl group, and a heterocyclic group are preferred, an aryl group and a heterocyclic group are more preferred, and an aryl group is particularly preferred.

As the linking group represented by Y^{A1}, a vinyl group, phenylene ring, a pyridine ring, pyrazine ring, or pyrimidine ring which are connected to the nitrogen atoms at 1- and 2-positions thereof, or an alkylene group containing from 1 to 8 carbon atoms is preferred, a vinyl group or phenylene ring which are connected to the nitrogen atoms at 1 and 2-positions thereof, or an alkylene group containing from 1 to 6 carbon atoms is more preferred, and a phenylene ring is particularly preferred.

The substituents represented by R^{A3} and R^{A4} may be connected to the linking group represented by Y^{A1} to form a ring. For example, in the case where Y^{A1} represents a phenylene group connected to the nitrogen atoms at 1- and 2-positions thereof, R^{A3} and R^{A4} may respectively be connected to 3- and 6-positions of the phenylene group to form a phenanthroline ring and may further have a substituent.

One of more preferred examples of the platinum complex phosphorescent material having a tetradentate ligand is a Pt complex represented by formula (B).

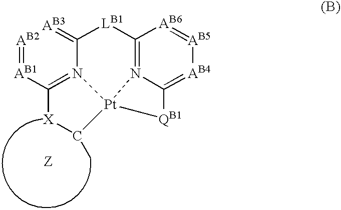

In formula (B), A^{B1} to A^{B6} each independently represents C—R or N; R represents a hydrogen atom or a substituent; L^{B1} represents a single bond or a divalent linking group; X represents C or N; Z represents a 5- or 6-membered aromatic ring or aromatic heterocyclic ring formed together with X—C; and Q^{B1} represents an anionic group bonding to Pt.

The formula (B) will be described below.

A^{B1} to A^{B6} each independently represents C—R or N. R represents a hydrogen atom or a substituent. The Substituent represented by R is the same as those which have been illustrated as the foregoing substituent group A, and a preferred scope thereof is also the same as described there.

A^{B1} to A^{B6} each is preferably C—R, and Rs may be connected to each other to form a ring. In the case where A^{B1} to A^{B6} each represents C—R, R in each of A^{B2} and A^{B5} is preferably a hydrogen atom, an alkyl group, an aryl group, an amino group, an alkoxy group, an aryloxy group, a fluorine atom or a cyano group; more preferably a hydrogen atom, an amino group, an alkoxy group, an aryloxy group or a fluorine atom; and particularly preferably a hydrogen atom or a fluorine atom, and R in each of A^{B1}, A^{B3}, A^{B4}, and A^{B6} is preferably a hydrogen atom, an alkyl group, an aryl group, an amino group, an alkoxy group, an aryloxy group, a fluorine atom or a cyano group; more preferably a hydrogen atom, an amino group, an alkoxy group, an aryloxy group or a fluorine atom; and particularly preferably a hydrogen atom.

L^{B1} represents a single bond or a divalent linking group.

Examples of the divalent linking group represented by L^{B1} include an alkylene group (e.g., methylene, ethylene or propylene), an arylene group (e.g., phenylene or naphthalenediyl), a heteroarylene group (e.g., pyridinediyl or thiophenediyl), an imino group (—NR—) (e.g., a phenylimino group), an oxy group (—O—), a thio group (—S—), a phosphinidene group (—PR—) (e.g., a phenylphosphinidene group), a silylene group (—SiRR′—) (e.g., a dimethylsilylene group or a diphenylsilylene group), and a combination thereof. These linking groups may further have a substituent.

L^{B1} represents preferably a single bond, an alkylene group, an arylene group, a heteroarylene group, an imino group, an oxy group, a thio group or a silylene group; more preferably a single bond, an alkylene group, an arylene group or an imino group; still more preferably an alkylene group; still more preferably a methylene group; still more preferably a di-substituted methylene group; still more preferably a dimethylmethylene group, a diethylmethylene group, a diisobutylmethylene group, a dibenzylmethylene group, an ethylmethylmethylene group, a methylpropylmethylene group, an isobutylmethylmethylene group, a diphenylmethylene group, a methylphenylmethylene group, a cyclohexanediyl group, a cyclopentanediyl group, a fluorenediyl group or a fluoromethylmethylene group; and particularly preferably a dimethylmethylene group, a diphenylmethylene group or a cyclohexanediyl group.

X represents C or N. Z represents a 5- or 6-membered aromatic hydrocarbon romg or heteroaromatic ring formed together with X—C. Examples of the aromatic hydrocarbon ring or heteroaromatic ring represented by Z include a benzene ring, a naphthalene ring, an anthracene ring, a pyrene ring, a phenanthrene ring, a perylene ring, a pyridine ring, a quinoline ring, an isoquinoline ring, a phenanthridine ring, a pyrimidine ring, a pyrazine ring, a pyridazine ring, a triazine ring, cinnoline ring, an acridine ring, a phthalazine ring, a quinazoline ring, a quinoxaline ring, a naphthyridine ring, a pteridine ring, a pyrrole ring, a pyrazole ring, a triazole ring, an indole ring, a carbazole ring, an indazole ring, a benzimidazole ring, an oxazole ring, a thiazole ring, an oxadiazole ring, a thiadiazole ring, a benzoxazole ring, a benzothiazole ring, an imidazopyridine ring, a thiophene ring, a benzothiophene ring, a furan ring, a benzofuran ring, a phosphole ring, a phosphinine ring, and a silole ring. Z may contain a substituent. As the substituent, those which have heretofore been illustrated as the substituent group A may be applied. In addition, Z may form a condensed ring together with other ring.

Z is preferably a benzene ring, a naphthalene ring, a pyrazole ring, an imidazole ring, a triazole ring, a pyridine ring, an indole ring or a thiophene ring, more preferably a benzene ring, a pyrazole ring or a pyridine ring.

Q^{B1} represents an anionic group connected to Pt. Examples of the anionic group represented by Q^{B1} include a vinyl ligand, an aromatic hydrocarbon ring ligand (e.g., a benzene ligand, a naphthalene ligand, an anthracene ligand or a phenanthrene ligand), a heterocyclic ligand (e.g., a furan ligand, a thiophene ligand, a pyridine ligand, a pyrazine ligand, a pyrimidine ligand, a pyridazine ligand, a triazine ligand, a thiazole ligand, an oxazole ligand, a pyrrole ligand, an imidazole ligand, a pyrazole ligand, a triazole ligand, and a ring-condensed ligand thereof (e.g., a quinoline ligand or a benzothiazole ligand). In this case, the bond between Pt and Q^{B1} may be any of covalent bond, ionic bond and coordination bond. As the atom in Q^{B1} connected to Pt, a carbon atom, a nitrogen atom, an oxygen atom, a sulfur atom, and a phosphorus atom are preferred, a carbon atom, an oxygen atom, and a nitrogen atom are more preferred, and a carbon atom is still more preferred.

The group represented by Q^{B1} is preferably an aromatic hydrocarbon ring ligand connected to Pt at the carbon atom thereof, an aromatic heterocyclic ligand connected to Pt at the carbon atom thereof, a nitrogen-containing aromatic heterocyclic ligand connected to Pt at the nitrogen atom thereof, or an acyloxy ligand, more preferably an aromatic hydrocarbon ring ligand connected to Pt at the carbon atom thereof, or an aromatic heterocyclic ligand connected to Pt at the carbon atom thereof. It is particularly preferred that the group represented by Q^{B1} is the same group as Z ring formed together with C—X in the formula (B).

The Pt complex represented by the formula (B) is more preferably a Pt complex represented by formula (C).

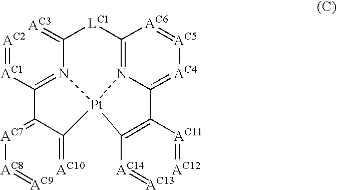

In formula (C), A^{C1} to A^{C14} each independently represents C—R or N. R represents a hydrogen atom or a substituent. L^{C1} represents a single bond or a divalent linking group.

The formula (C) will be described below.

A^{C1} to A^{C14} each independently represents C—R or N. R represents a hydrogen atom or a substituent. A^{C1} to A^{C6} are the same as A^{B1} to A^{B6} in the foregoing formula (B), and a preferred scope thereof are also the same as described there.

Regarding A^{C7} to A^{C14}, the number of N (nitrogen atom) among A^{C7} to A^{C10} and the number of N among A^{C11} to A^{C14} each is preferably from 0 to 2, more preferably from 0 to 1. Members representing N are selected from among A^{C8} to A^{C10} and among A^{C12} to A^{C14}, more preferably from among A^{C8}, A^{C9}, A^{C12}, and A^{C13}, particularly preferably from among A^{C8} and A^{C12}.

In the case where A^{C7} to A^{C14} each represents C—R, R in each of A^{C8} and A^{C12} is preferably a hydrogen atom, an alkyl group, a polyfluoroalkyl group, an aryl group, an amino group, an alkoxy group, an aryloxy group, a fluorine atom or a cyano group; more preferably a hydrogen atom, a polyfluoroalkyl group, an alkyl group, an aryl group, a fluorine atom or a cyano group; and particularly preferably a hydrogen atom, a polyfluoroalkyl group or a cyano group. R in each of A^{C7}, A^{C9}, A^{C11}, and A^{C13} is preferably a hydrogen atom, an alkyl group, a polyfluoroalkyl group, an aryl group, an amino group, an alkoxy group, an aryloxy group, a fluorine atom or a cyano group; more preferably a hydrogen atom, a polyfluoroalkyl group, a fluorine atom or a cyano group; and particularly preferably a hydrogen atom or a fluorine atom. R in each of by A^{C7} and A^{C9} is preferably a hydrogen atom or a fluorine atom, more preferably a hydrogen atom. In the case where any two of A^{C7} to A^{C9} and A^{C11} to A^{C13} represent C—R, Rs may be connected to each other to form a ring.

The linking group represented by L^{C1} is the same as the linking group represented by L^{B1} in the foregoing formula (B), and a preferred scope thereof is also the same as described there.

The Pt complex represented by the formula (B) is more preferably a Pt complex represented by formula (D).

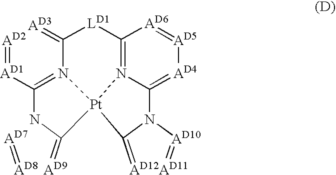

In formula (D), A^{D1} to A^{D12} each independently represents C—R or N. R represents a hydrogen atom or a substituent. L^{D1} represents a single bond or a divalent linking group.

The formula (D) will be described below.

A^{D1} to A^{D12} each independently represents C—R or N. R represents a hydrogen atom or a substituent.

A^{D1} to A^{D6} are the same as A^{B1} to A^{B6} in the foregoing formula (B), and a preferred scope thereof is also the same as described there.

Regarding A^{D7} to A^{D12}, the number of N (nitrogen atom) among A^{D7} to A^{D9} and the number of N among A^{D10} to A^{D12} each is preferably from 0 to 2, more preferably from 0 to 1, particularly preferably 1. Members representing N are selected from among A^{D7} to A^{D9} and among A^{D10} to A^{D12}, more preferably from among A^{D7}, A^{D9}, A^{D10}, and A^{D12}, particularly preferably from among A^{D7} and A^{D10}.

In the case where A^{D7} to A^{D12} each represents C—R, R represented by A^{D8} and A^{D11} is preferably a hydrogen atom, an alkyl group, a polyfluoroalkyl group, an aryl group, an amino group, an alkoxy group, an aryloxy group, a fluorine atom or a cyano group; more preferably a hydrogen atom, a polyfluoroalkyl group, an alkyl group, an aryl group, a fluorine atom or a cyano group; and particularly preferably a polyfluoroalkyl group (e.g., a trifluoromethyl group or a perfluoroethyl group) or a cyano group. R in each of A^{D7}, A^{D9}, A^{D10}, and A^{D12} is preferably a hydrogen atom, an alkyl group, a polyfluoroalkyl group, an aryl group, an amino group, an alkoxy group, an aryloxy group, a fluorine atom or a cyano group; more preferably a hydrogen atom, a hydrogen atom or a fluorine atom; and particularly preferably a hydrogen atom. In the case where any two of A^{D7} to A^{D12} represent C—R, Rs may be connected to each other to form a ring.

The linking group represented by L^{D1} is the same as the linking group represented by L^{B1} in the foregoing formula (B), and a preferred scope thereof is also the same as described there.

One of more preferred examples of the platinum complex (phosphorescent material) is a Pt complex represented by formula (E).

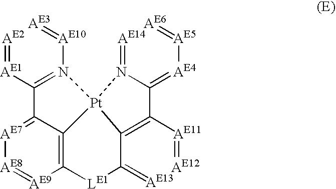

In formula (E), A^{E1} to A^{E14} each independently represents C—R or N; R represents a hydrogen atom or a substituent; and L^{E1} represents a single bond or a divalent linking group.

The formula (E) will be described below.

A^{E1} to A^{E12} each independently represents C—R or N. R represents a hydrogen atom or a substituent. A^{E1} to A^{E6} are the same as A^{B1} to A^{B6} in the foregoing formula (B), and a preferred scope thereof is also the same as described there. A^{E7} to A^{E14} are the same as A^{C7} to A^{C14} in the foregoing formula (C), and a preferred scope thereof is also the same as described there.

The linking group represented by L^{E1} is the same as the linking group represented by L^{B1} in the foregoing formula (B).

L^{E1} represents preferably a single bond, an alkylene group, an arylene group, a heteroarylene group, an imino group, an oxy group, a thio group or a silylene group; more preferably an alkylene group, an imino group, an oxy group, a thio group or a silylene group; still more preferably an alkylene group; still more preferably a methylene group; still more preferably a di-substituted methylene group; still more preferably a dimethylmethylene group, a diethylmethylene group, a diisobutylmethylene group, a dibenzylmethylene group, an ethylmethylmethylene group, a methylpropylmethylene group, an isobutylmethylmethylene group, a diphenylmethylene group, a methylphenylmethylene group, a cyclohexanediyl group, a cyclopentanediyl group, a fluorenediyl group or a fluoromethylmethylene group; and particularly preferably a dimethylmethylene group, a diphenylmethylene group or a cyclohexanediyl group.

One of more preferred examples of the platinum complex (phosphorescent material) is a Pt complex represented by the following formula (F).

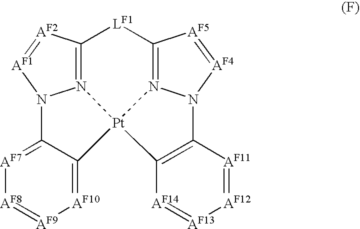

In formula (F), A^{F1} to A^{F14} each independently represents C—R or N; R represents a hydrogen atom or a substituent; and LFl represents a single bond or a divalent linking group.

The formula (F) will be described below.

A^{F1} to A^{F14} each independently represents C—R or N. R represents a hydrogen atom or a substituent. A^{F1} to A^{F5} are the same as A^{B1} to A^{B5} in the foregoing formula (B). A^{F1} to A^{F5} each is preferably C—R, and Rs may be connected to each other to form a ring. In the case where A^{F1} to A^{F5} each is C—R, R in each of A^{F1} to A^{F5} is preferably a hydrogen atom, an alkyl group, an aryl group, an amino group, an alkoxy group, an aryloxy group, a fluorine atom or a cyano group; more preferably a hydrogen atom, an aryl group, a fluorine atom or a cyano group; particularly preferably a hydrogen atom.

A^{F7} to A^{F14} are the same as A^{C7} to A^{C14} in the foregoing formula (C), and a preferred scope thereof is also the same as described there. In particular, in the case where any two of A^{C7} to A^{C9} and A^{C11} to A^{C13} represent C—R, the ring structure formed by Rs connected to each other is preferably a furan ring, a benzofuran ring, a pyrrole ring, a benzopyrrole ring, a thiophene ring, a benzothiophene ring or a fluorine ring. These rings may further have a substituent.

The linking group represented by L^{F1} is the same as the linking group represented by L^{B1} in the foregoing formula (B), and a preferred scope thereof is also the same.

Specific examples of the light-emitting materials are illustrated below which, however, are not to be construed to limit the invention in any way.

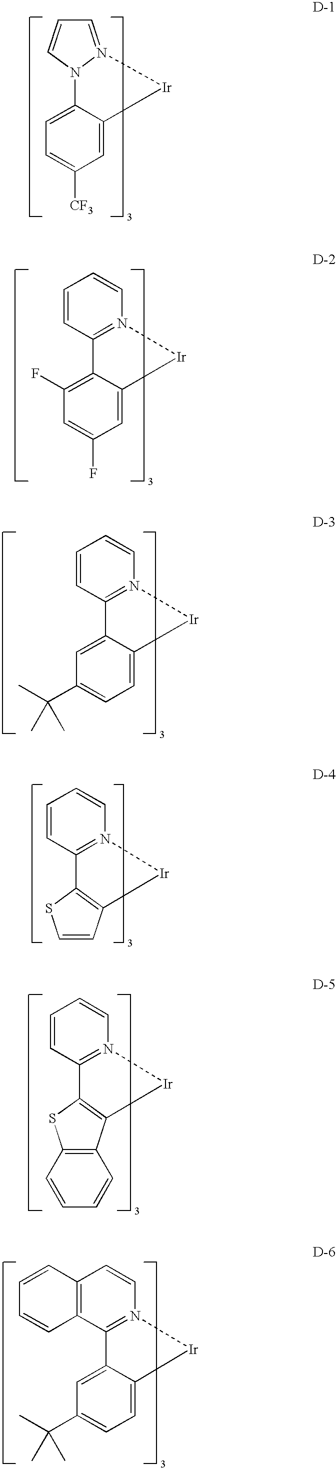

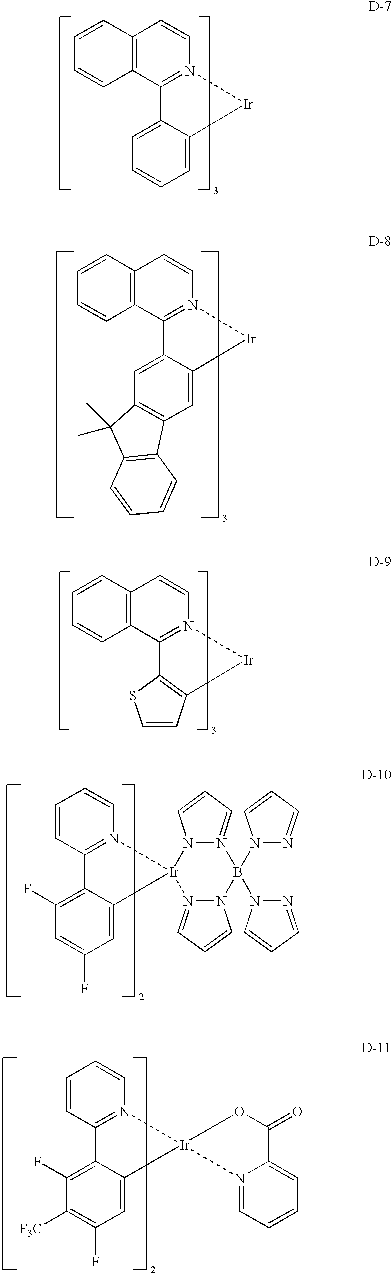

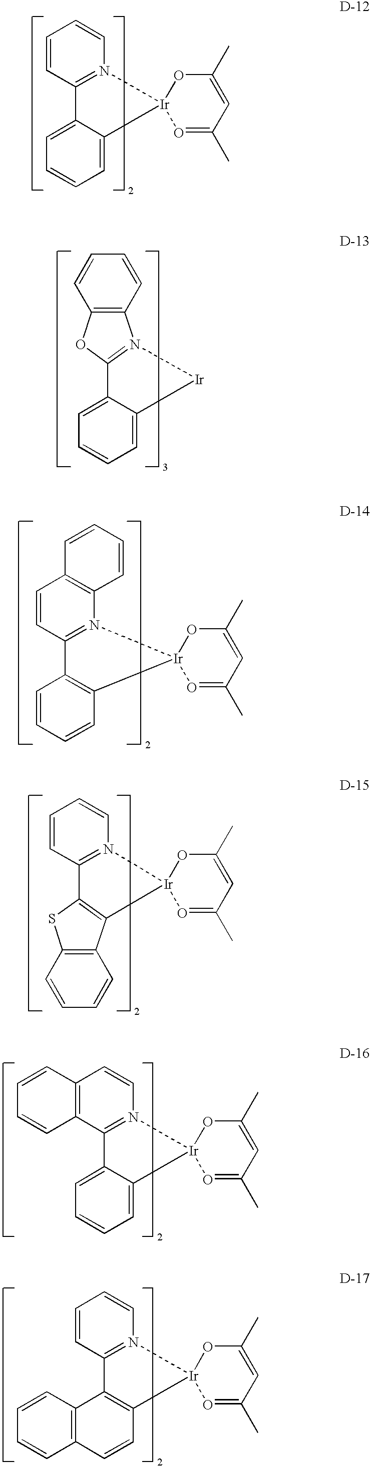

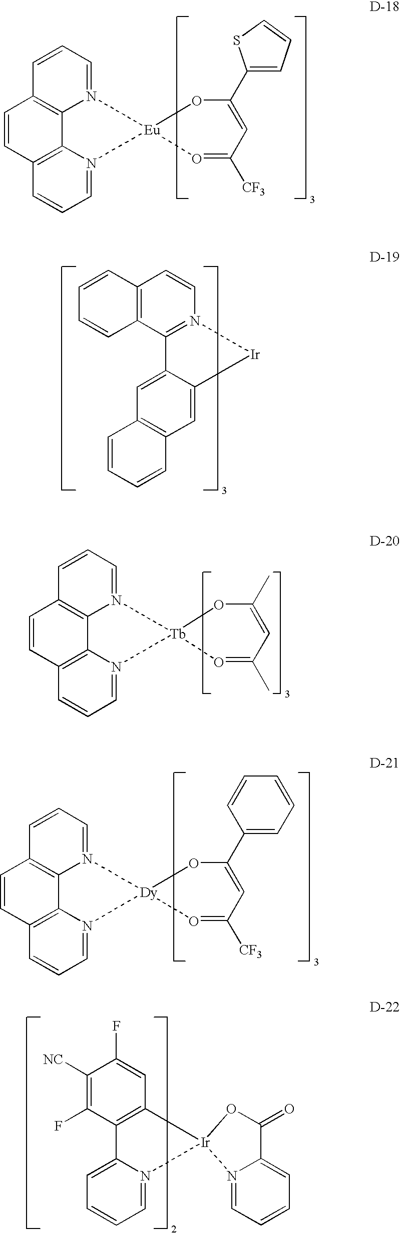

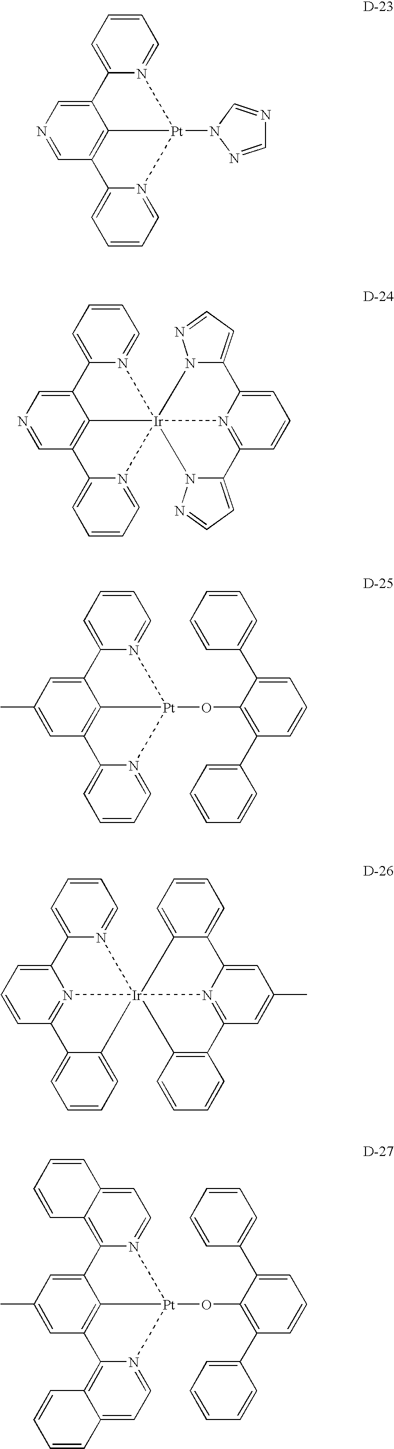

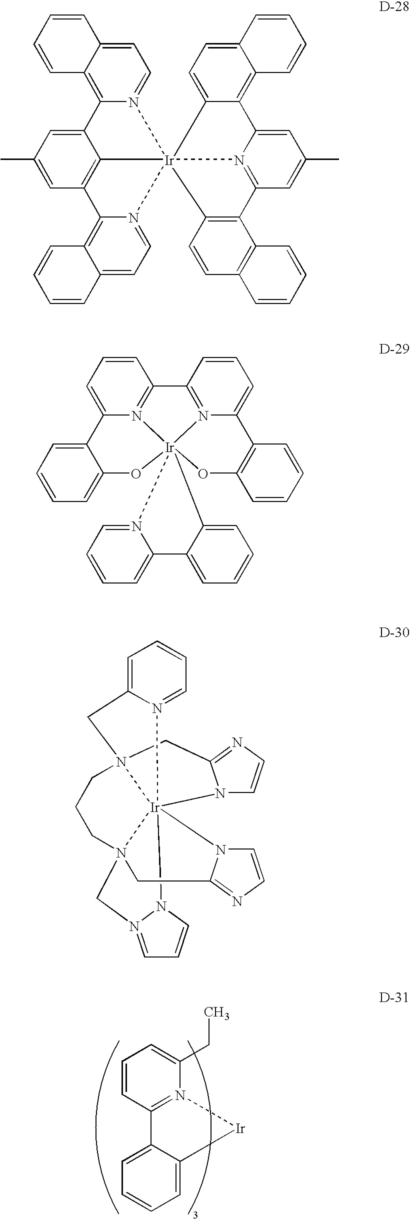

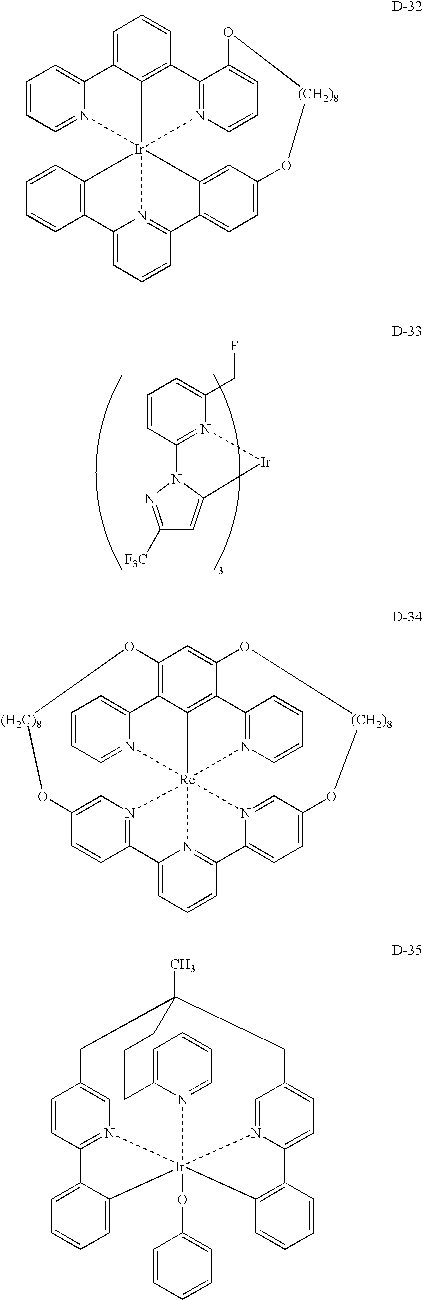

Also, examples of the platinum complex capable of emitting phosphorescence and containing a tetradentate ligand are illustrated below which, however, are not limitative at all.

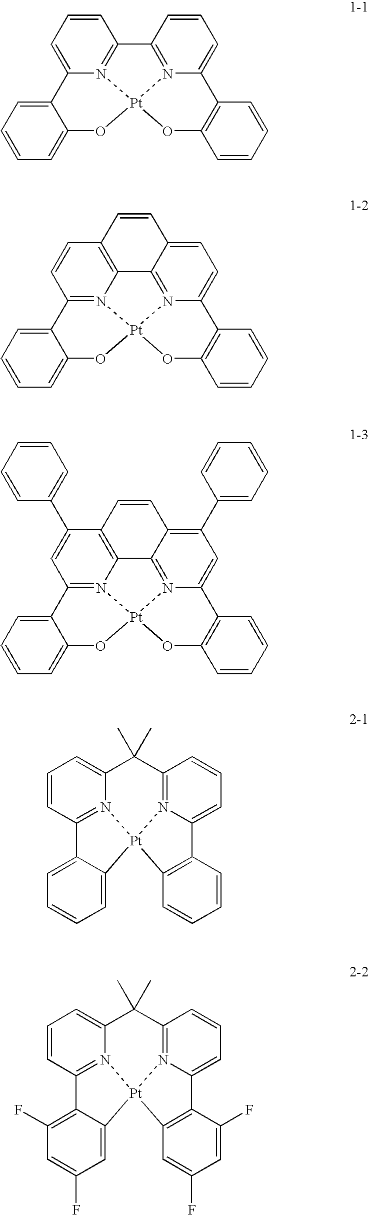

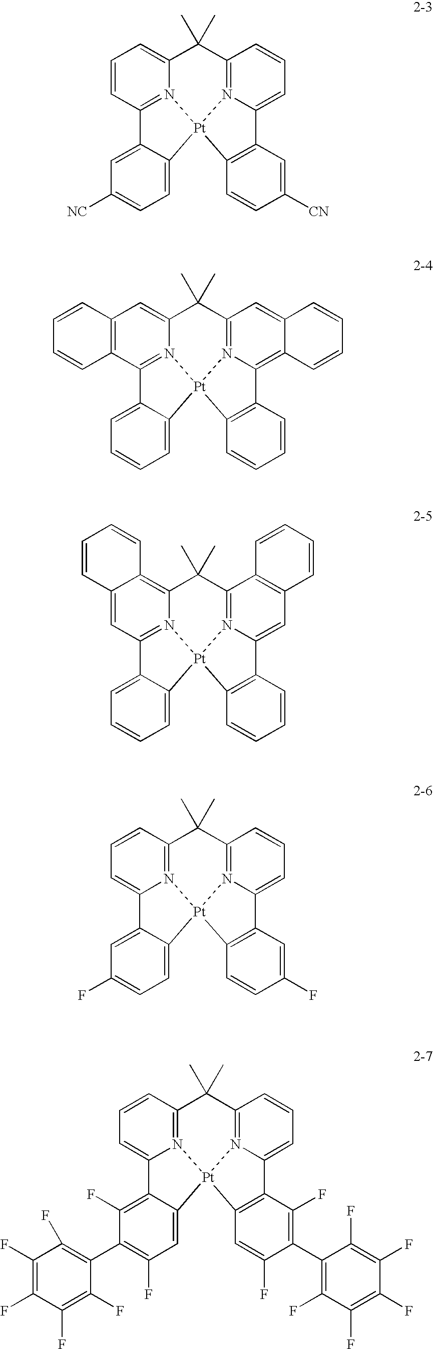

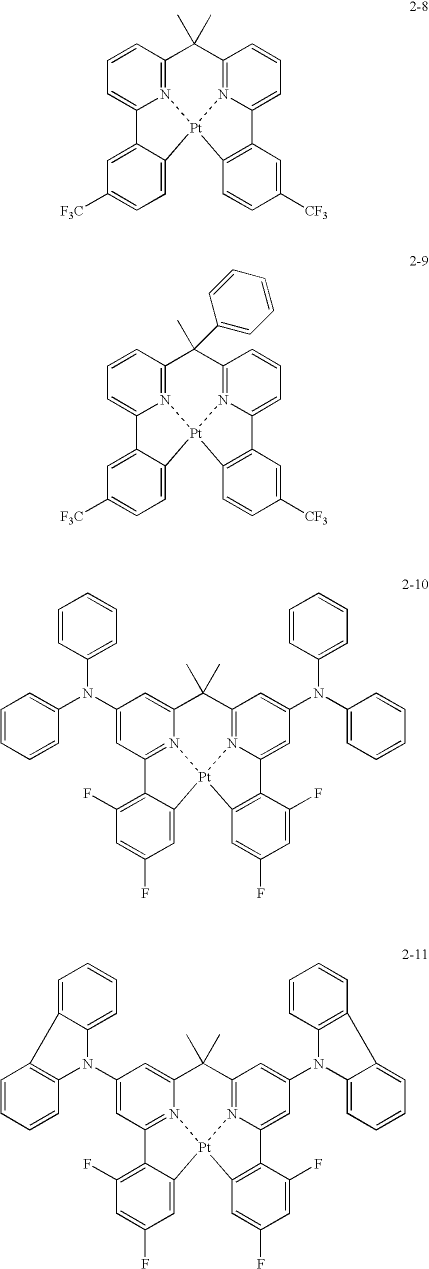

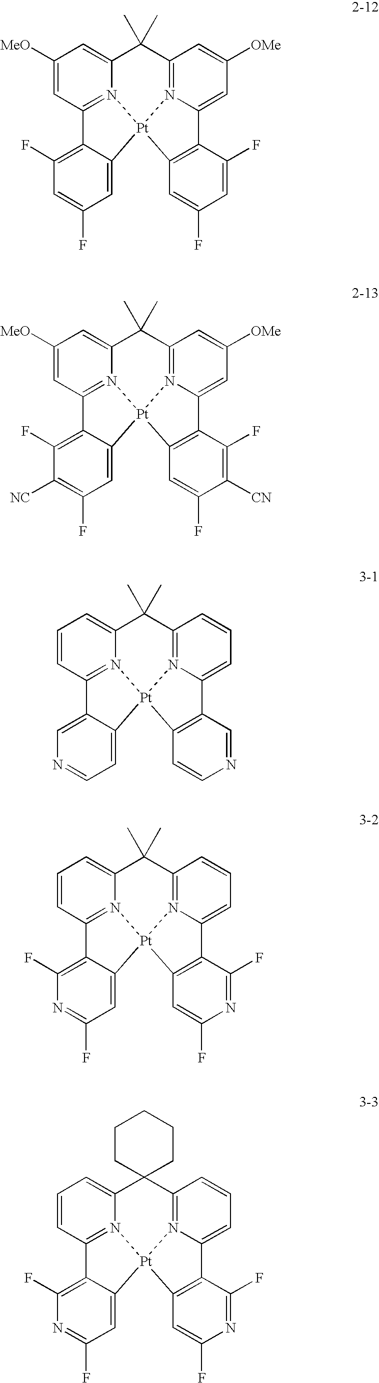

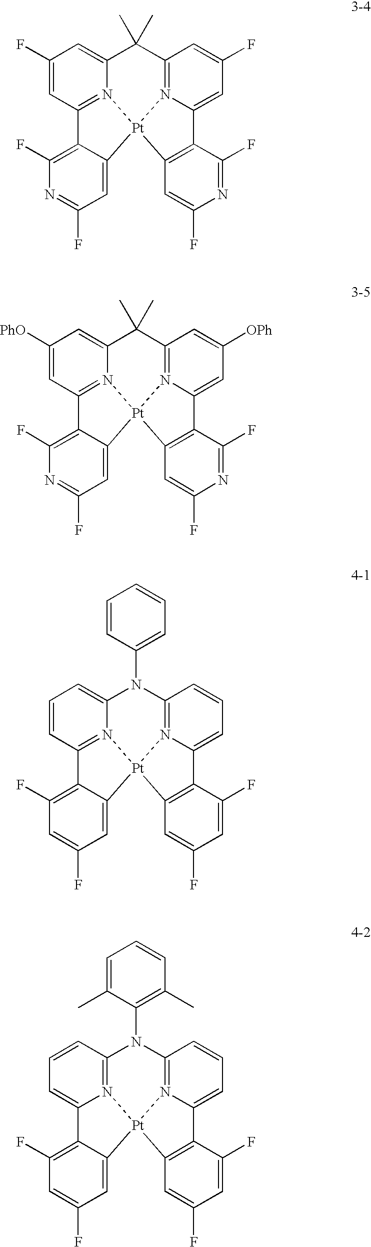

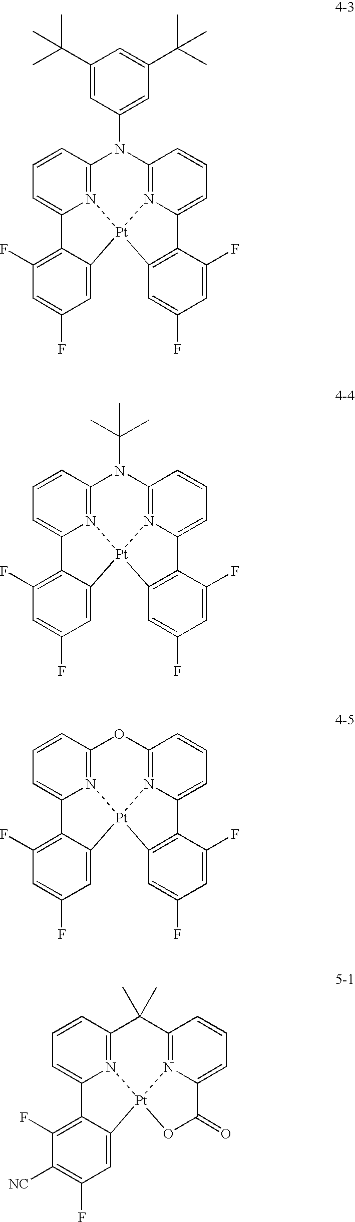

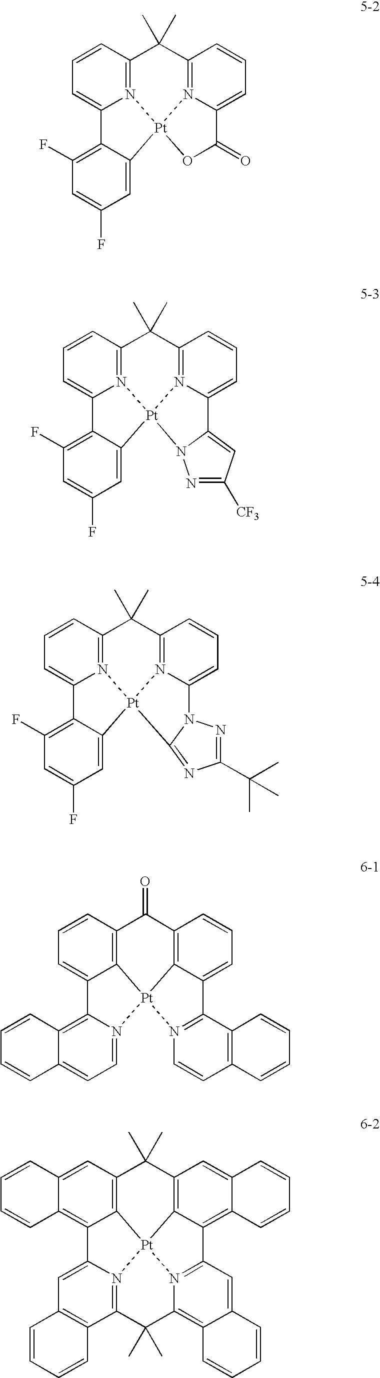

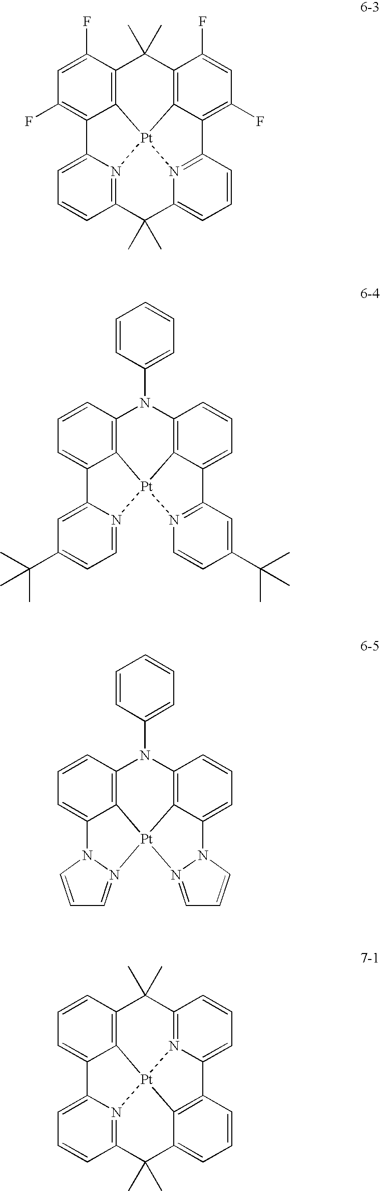

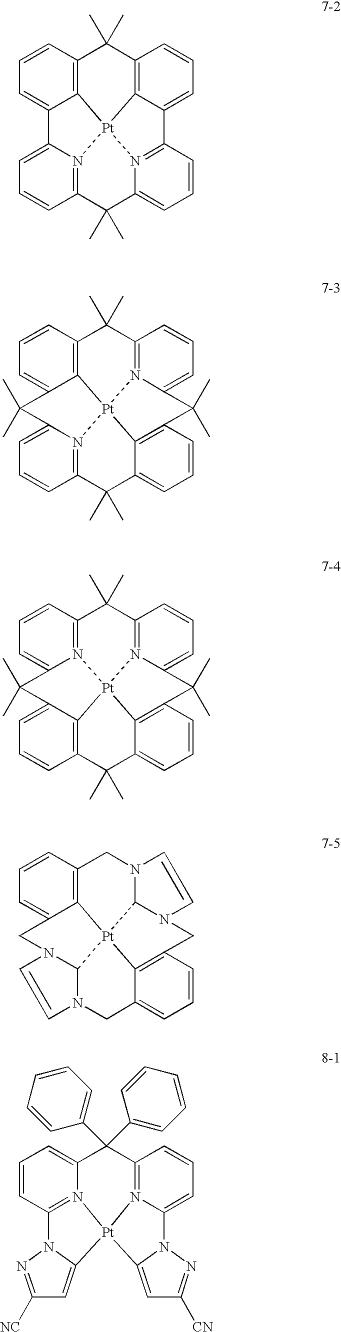

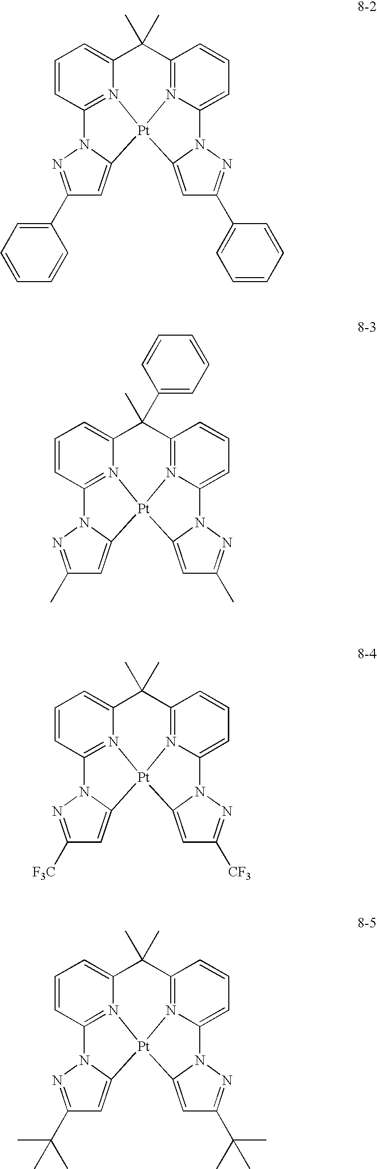

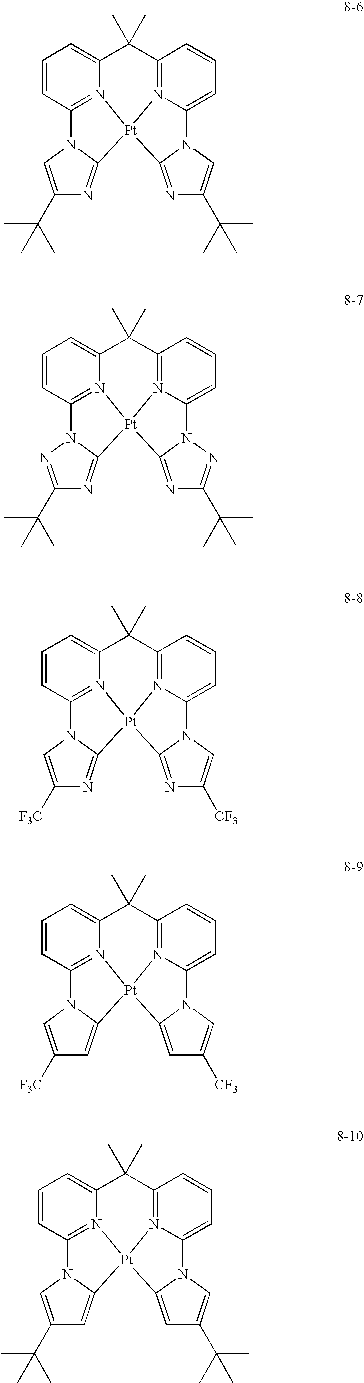

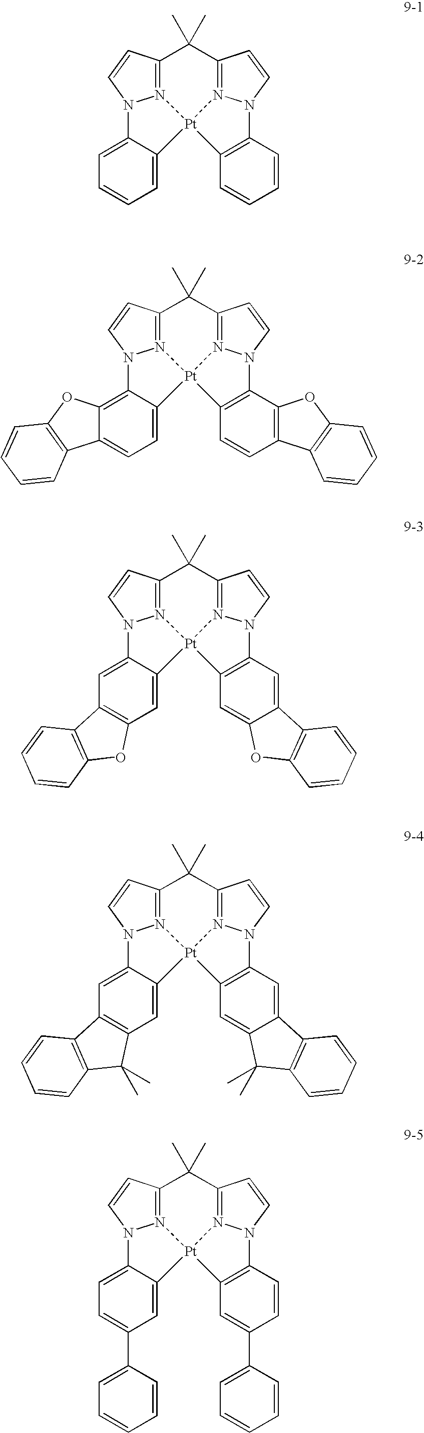

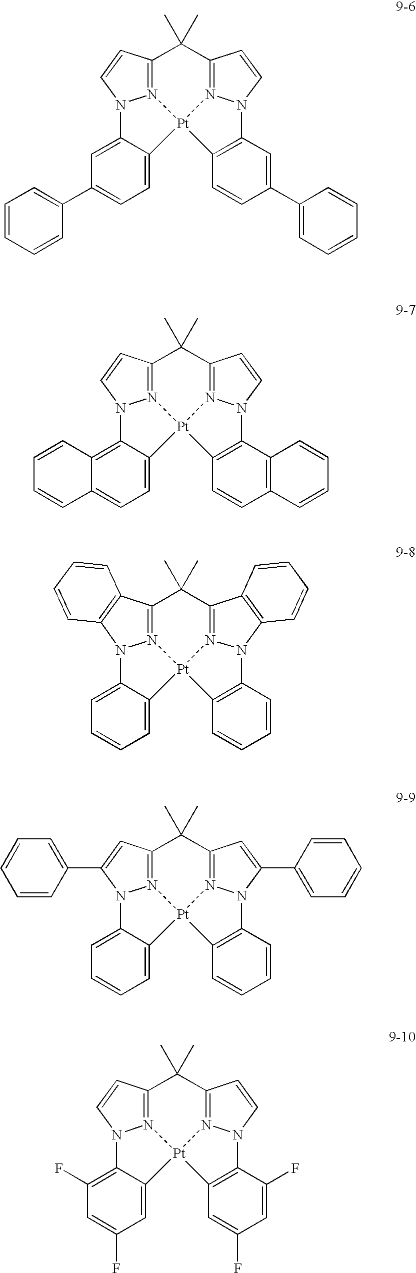

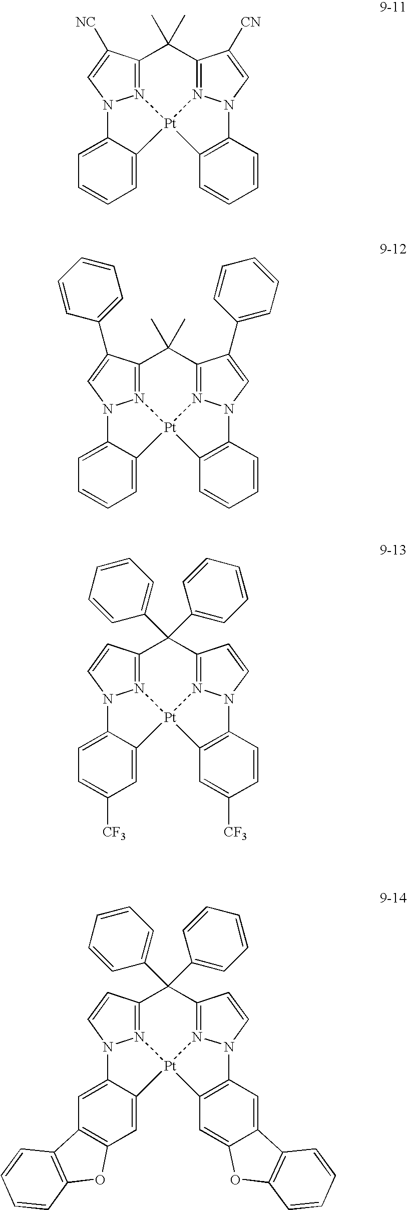

The light-emitting material is incorporated in the light-emitting layer in an amount of generally from 0.1 to 50% by weight (% by mass) based on the weight of all the compounds forming the light-emitting layer and, in view of durability and external quantum efficiency, in an amount of preferably from 1 to 50% by weight, more preferably from 2 to 40% by weight.

The phosphorescent material is preferably contained in an amount of from 0.1 to 40% by weight, more preferably from 0.5 to 20% by weight.

The thickness of the light-emitting layer is not particularly limited, but is usually preferably from 1 to 500 nm, and in view of external quantum efficiency, the thickness is more preferably from 5 to 200 nm, still more preferably from 10 to 100 nm.

### (Hole Injecting Layer and Hole Transporting Layer)

The hole injecting layer and the hole transporting layer are layers having a function to receive holes from the anode or anode side and transport the holes to the cathode side. The hole injecting layer and the hole transporting layer are specifically preferably the layers containing carbazole derivatives, triazole derivatives, oxazole derivatives, oxadiazole derivatives, imidazole derivatives, polyarylalkane derivatives, pyrazoline derivatives, pyrazolone derivatives, phenylenediamine derivatives, arylamine derivatives, amino-substituted chalcone derivatives, styrylanthracene derivatives, fluorenone derivatives, hydrazone derivatives, stilbene derivatives, silazane derivatives, aromatic tertiary amine compounds, styrylamine compounds, aromatic dimethylidyne compounds, porphyrin compounds, organic silane derivatives, carbon, and various kinds of metal complexes represented by Ir complex, having phenylazole, or phenylazine as the ligand.

The thickness of the hole injecting layer and hole transporting layer is preferably 500 nm or less from the viewpoint of lowering driving voltage.

The thickness of the hole transporting layer is preferably from 1 to 500 nm, more preferably from 5 to 200 nm, and still more preferably from 10 to 100 nm. The thickness of the hole injecting layer is preferably from 0.1 to 200 nm, more preferably from 0.5 to 100 nm, and still more preferably from 1 to 100 nm.

The hole injecting layer and the hole transporting layer may be a single layer structure including one or two or more of the above materials, or may be a multilayer including comprising a plurality of layers of the same or different compositions.

### (Electron Injecting Layer and Electron Transporting Layer)

The electron injecting layer and the electron transporting layer are layers having a function to receive electrons from the cathode or cathode side and transport the electrons to the anode side. The electron injecting layer and the electron transporting layer are specifically preferably layers containing triazole derivatives, oxazole derivatives, oxadiazole derivatives, imidazole derivatives, fluorenone derivatives, anthraquinodimethane derivatives, anthrone derivatives, diphenylquinone derivatives, thiopyran dioxide derivatives, carbodiimide derivatives, fluorenylidenemethane derivatives, distyrylpyrazine derivatives, tetracarboxylic anhydride of aromatic rings such as naphthalene, perylene, etc., a phthalocyanine derivative, various metal complexes represented by metal complexes of 8-quinolinol derivatives or metalphthalocyanine and metal complexes having benzoxazole, benzothiazole as the ligand, and organic silane derivative, etc.

The thickness of each of the electron injecting layer and electron transporting layer is preferably 500 nm or less from the viewpoint of lowering driving voltage.

The thickness of the electron transporting layer is preferably from 1 to 500 nm, more preferably from 5 to 200 nm, and still more preferably from 10 to 100 nm. The thickness of the electron injecting layer is preferably from 0.1 to 200 nm, more preferably from 0.2 to 100 nm, and still more preferably from 0.5 to 50 nm.

The electron injecting layer and the electron transporting layer may be a single layer structure comprising one or two or more of the above materials, or may be a multilayer structure comprising a plurality of layers of the same or different compositions.

### (Hole Blocking Layer)

A hole blocking layer is a layer having a function of preventing holes transported from the anode side to the light-emitting layer from passing through to the cathode side. In the invention, a hole blocking layer can be provided as the organic layer contiguous to the light-emitting layer on the cathode side.

As the examples of the organic compounds constituting the hole blocking layer, aluminum complexes, e.g., BAlq, etc., triazole derivatives, phenanthroline derivatives, e.g., BCP, etc., can be exemplified.

The thickness of the hole blocking layer is preferably from 1 to 500 nm, more preferably from 5 to 200 nm, and still more preferably from 10 to 100 nm.

The hole blocking layer may be a single layer structure comprising one or two or more of the above materials, or may be a multilayer structure comprising a plurality of layers of the same or different compositions.

### (Protective Layer)

In the invention, an organic electroluminescent device may be completely protected with a protective layer.

It is sufficient for the materials to be contained in the protective layer to have a function capable of restraining the substances accelerating deterioration of elemental device, e.g., water, oxygen, etc., from entering the device.

The specific examples of such materials include metals, e.g., In, Sn, Pb, Au, Cu, Ag, Al, Ti, Ni, etc., metal oxides, e.g., MgO, SiO, SiO₂, Al₂O₃, GeO, NiO, CaO, BaO, Fe₂O₃, Y₂O₃, TiO₂, etc., metal nitrides, e.g., SiNₓ, SiNₓO_{y}, etc., metal fluorides, e.g., MgF₂, LiF, AlF₃, CaF₂, etc., polyethylene, polypropylene, polymethyl methacrylate, polyimide, polyurea, polytetrafluoroethylene, polychlorotrifluoroethylene, polydichlorodifluoroethylene, copolymers of chlorotrifluoroethylene with dichlorodifluoroethylene, copolymers obtained by copolymerization of a monomer mixture containing tetrafluoroethylene and at least one comonomer, fluorine-containing copolymers having a cyclic structure on the main chain of the copolymer, water absorptive substances having a water absorption rate of not lower than 1%, and moisture proofing substances having a water absorption rate of not higher than 0.1%.

The forming method of the protective layer is not especially restricted and, for example, a vacuum deposition method, a sputtering method, a reactive sputtering method, an MBE (molecular beam epitaxy) method, a cluster ion beam method, an ion plating method, a plasma polymerization method (a high frequency excitation ion plating method), a plasma CVD method, a laser CVD method, a heat CVD method, a gas source CVD method, a coating method, a printing method, a transfer method, etc., can be applied to the invention.

### (Sealing)

An organic electroluminescent device of the invention may be completely sealed in a sealing container.

Further, a water absorber or an inert liquid may be filled in the space between the sealing container and the light-emitting device. The water absorber is not especially restricted and, for example, barium oxide, sodium oxide, potassium oxide, calcium oxide, sodium sulfate, calcium sulfate, magnesium sulfate, phosphorus pentoxide, calcium chloride, magnesium chloride, copper chloride, cesium fluoride, niobium fluoride, calcium bromide, vanadium bromide, molecular sieve, zeolite, magnesium oxide, etc., can be exemplified. The inert liquid is not particularly limited and, for example, paraffins, liquid paraffins, fluorine solvents, such as perfluoroalkane, perfluoroamine, perfluoroether, etc., chlorine solvents, and silicone oils are exemplified.

In an organic electroluminescent device, luminescence can be obtained by the application of DC (if necessary, an alternating current factor may be contained) voltage (generally from 2 to 15 V) or DC electric current between the anode and cathode of a device of the invention.

In connection with the driving methods of a device of the invention, the driving methods disclosed in JP-A-2-148687, JP-A-6-301355, JP-A-5-29080, JP-A-7-134558, JP-A-8-234685, JP-A-8-241047, Japanese Patent No. 2784615, and U.S. Pat. No. 5,828,429 and U.S. Pat. No. 6,023,308 can be used.

The external quantum efficiency of a light-emitting device of the invention is preferably 5% or more, more preferably 10% or more, and still more preferably 13% or more. As the value of external quantum efficiency, the maximum value of the external quantum efficiency at the time of driving a device at 20° C., or the value of the external quantum efficiency near 100 to 300 cd/m² at the time of driving a device at 20° C. can be used.

The internal quantum efficiency of a light-emitting device of the invention is preferably 30% or more, more preferably 50% or more, and still more preferably 70% or more. The internal quantum efficiency of a device is computed by dividing the external quantum efficiency by the efficiency of light outcoupling. In ordinary organic electroluminescent devices, the efficiency of light outcoupling is about 20%, but it is possible to make the efficiency of light outcoupling 20% or more by various contrivances such as the shape of a substrate, the shape of electrodes, the thickness of an organic layer, the thickness of an inorganic layer, the refractive index of an organic layer, and the refractive index of an inorganic layer.

A light-emitting device of the invention has a maximum intensity wavelength of emission spectrum in the range of preferably from 350 to 700 nm, more preferably from 350 to 600, still more preferably from 400 to 550 nm, and especially preferably from 430 to 500 nm.

### EXAMPLES

The invention will be described with reference to examples, but the invention should not be construed as being restricted thereto.

### <Synthesis of Exemplified Compound 1>

Exemplified compound 1 is synthesized according to the following scheme.

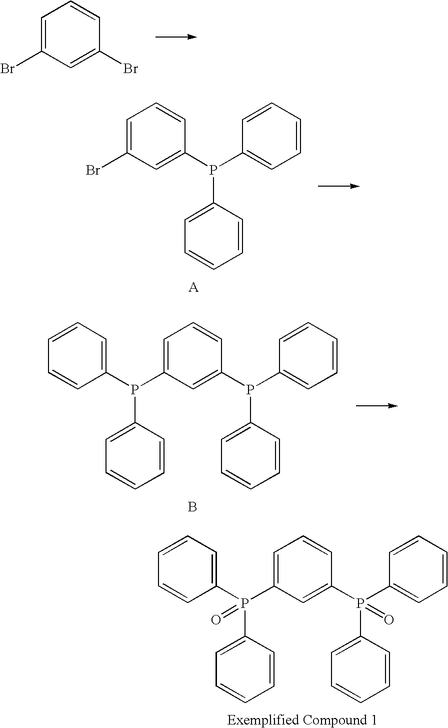

### (Synthesis of Intermediate A)

n-Butyl lithium (a 1.6M hexane solution) (28 ml) was put into a three-neck flask having a capacity of 500 ml, and cooled to −72° C. with a dry ice/acetone bath. A THF solution (200 ml) containing 5.1 ml of m-dibromobenzene was added dropwise over 30 minutes. Subsequently, 7.5 ml of chlorodiphenylphosphine was added dropwise to the above mixture over 20 minutes, and after the mixture was stirred at −70° C. for 30 minutes, the cooling bath was taken off, followed by stirring at room temperature for 3.5 hours. Methanol (50 ml) was added to the reaction mixture. The solvent was removed under reduced pressure, liquid phase separation was performed with ethyl acetate and water, and an oily substance obtained by washing was separated by silica gel column chromatography to obtain 13 g of Intermediate A. Yield: 91%.

### (Synthesis of Intermediate B)

n-Butyl lithium (a 1.6M hexane solution) (9.1 ml) was put into a three-neck flask having a capacity of 200 ml, and cooled to −72° C. with a dry ice/acetone bath. A THF solution (60 ml) containing 5.0 g of intermediate A was added dropwise thereto over 15 minutes. Subsequently, 2.6 ml of chlorodiphenylphosphine was added dropwise to the above mixture over 15 minutes, and after stirring at −75° C. for 15 minutes, the mixture was taken out of the cooling bath, followed by stirring at room temperature for 3.5 hours. Methanol (20 ml) was added to the reaction mixture. The solvent was removed under reduced pressure, liquid phase separation is performed with ethyl acetate and water, and oily substance obtained by washing was separated by silica gel column chromatography to obtain 5.2 g of intermediate B. Yield: 80%.

### (Synthesis of Exemplified Compound 1)

Intermediate B (2.5 g) and 30 ml of dichloromethane were put in a recovery flask having a capacity of 100 ml, and 5.6 ml of a 30% aqueous hydrogen peroxide was added dropwise thereto, and the mixture was stirred for 8 hours as it was. An organic layer was separated by adding 50 ml of water and washed three times every time with 50 ml of water. A product was isolated by silica gel column chromatography and recrystallized with toluene-hexane to obtain 2.5 g of exemplified compound 1. Yield: 93%. T₁ level in the solid film of exemplified compound 1 was 81 kcal/mol. (A thin film was formed with the material on a cleaned quartz glass substrate in a thickness of about 50 nm by vacuum deposition. The spectrum of emission of phosphorescence of the thin film was measured with a fluorescence spectrophotometer Model F-7000 (manufactured by Hitachi High Technologies) under a liquid nitrogen temperature. The T₁ value was obtained by converting the rising wavelength at the end of the short wavelength side of the spectrum to energy.)

### <Synthesis of Exemplified Compound 4>

Exemplified compound 4 is synthesized according to the following scheme.

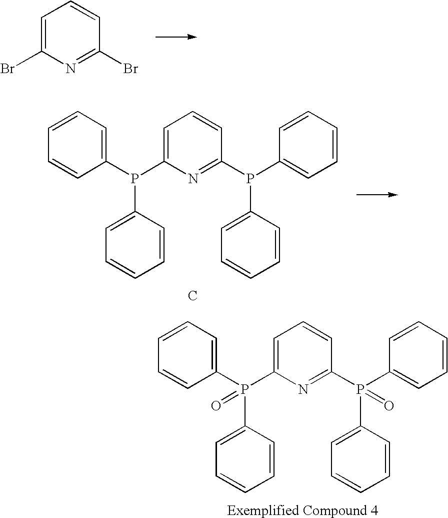

### (Synthesis of Intermediate C)

2,6-Dibromopyridine (3.55 g), 2.46 g of sodium acetate, 7.5 mg of palladium acetate, and 20 ml of dimethylacetamide were put in a three-neck flask having a capacity of 200 ml, and the mixture was stirred under nitrogen atmosphere. Under stirring, 83 ml of diphenylphosphine (a 10% hexane solution) was added dropwise to the mixture, and hexane is removed in an oil bath by raising the temperature to 100° C. After that, the temperature was further raised to 130° C. and stirring was continued for 4 hours with heating. After cooling to room temperature, extraction was performed with ethyl acetate. An organic phase was washed with water and saturated brine in order, and dried with magnesium sulfate to distill off the solvent. An oily substance obtained was separated by silica gel column chromatography to obtain 5.81 g of intermediate C. Yield: 87%.

### (Synthesis of Exemplified Compound 4)

Intermediate C (3.7 g) and 30 ml of dichloromethane were put in a recovery flask having a capacity of 100 ml, and 8.3 ml of a 30% aqueous hydrogen peroxide was added dropwise thereto. The mixture was stirred for 5 hours as it was. An organic layer was separated by adding 50 ml of water and washed three times every time with 50 ml of water. A product was isolated by silica gel column chromatography to obtain 3.4 g of exemplified compound 4. Yield: 86%. T₁ level in the solid film of exemplified compound 4 was 78 kcal/mol. (A thin film was formed with the material on a cleaned quartz glass substrate in a thickness of about 50 nm by vacuum deposition. The spectrum of emission of phosphorescence of the thin film was measured with a fluorescence spectrophotometer Model F-7000 (manufactured by Hitachi High Technologies) under a liquid nitrogen temperature. The T₁ value was obtained by converting the rising wavelength at the end of the short wavelength side of the spectrum to energy.)

### <Synthesis of Exemplified Compound 7>

Exemplified compound 7 is synthesized according to the following scheme.

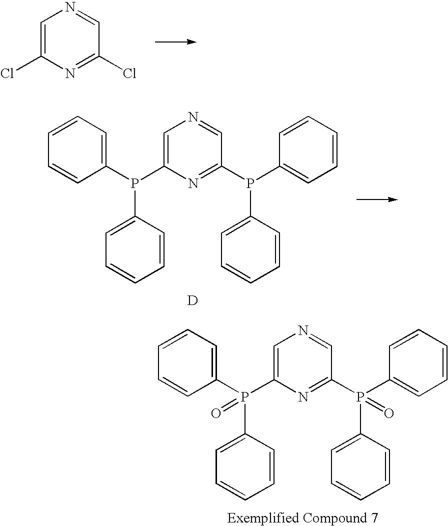

### (Synthesis of Intermediate D)

2,6-Dichloropyrazine (1.48 g), 1.64 g of sodium acetate, 5 mg of palladium acetate, and 20 ml of dimethylacetamide were put in a three-neck flask having a capacity of 200 ml, and the mixture was stirred under nitrogen atmosphere. Under stirring, 55 ml of diphenylphosphine (a 10% hexane solution) was added dropwise to the mixture, and hexane was removed in an oil bath by raising the temperature to 100° C. After that, the temperature was further raised to 130° C. and stirring is continued for 4 hours with heating. After cooling to room temperature, extraction is performed with ethyl acetate. An organic phase was washed with water and saturated brine in order, and dried with magnesium sulfate to distill off the solvent. An oily substance obtained was separated by silica gel column chromatography to obtain 1.12 g of intermediate D. Yield: 25%.

### (Synthesis of Exemplified Compound 7)

Intermediate D (1.02 g) and 20 ml of dichloromethane were put in a recovery flask having a capacity of 100 ml, and 2.5 ml of a 30% aqueous hydrogen peroxide was added dropwise thereto. The mixture was stirred for 5 hours as it was. An organic layer was separated by adding 30 ml of water and washed three times every time with 50 ml of water. A product was isolated by silica gel column chromatography to obtain 1.0 g of exemplified compound 7. Yield: 93%. T₁ level in the solid film of exemplified compound 7 was 68 kcal/mol. (A thin film was formed with the material on a cleaned quartz glass substrate in a thickness of about 50 nm by vacuum deposition. The spectrum of emission of phosphorescence of the thin film was measured with a fluorescence spectrophotometer Model F-7000 (manufactured by Hitachi High Technologies) under a liquid nitrogen temperature. The T₁ value was obtained by converting the rising wavelength at the end of the short wavelength side of the spectrum to energy.)

### <Evaluation of Organic Electroluminescent Device>

### (Calculation of External Quantum Efficiency)

Each device was subjected to application of DC constant voltage with a source measure unit Model 2400 (manufactured by Toyo Technica Co., Ltd.) to emit light. The emission luminance was measured by the luminance meter SR-3 manufactured by TOPCON. The emission spectrum and emission wavelength were measured by the spectrum analyzer PMA-11 manufactured by Hamamatsu Photonics K.K. Based on these data, the external quantum efficiency at the luminance of 1000 cd/m was obtained by the luminance conversion method.

The structural formulae of the compounds for use in the examples are shown below.

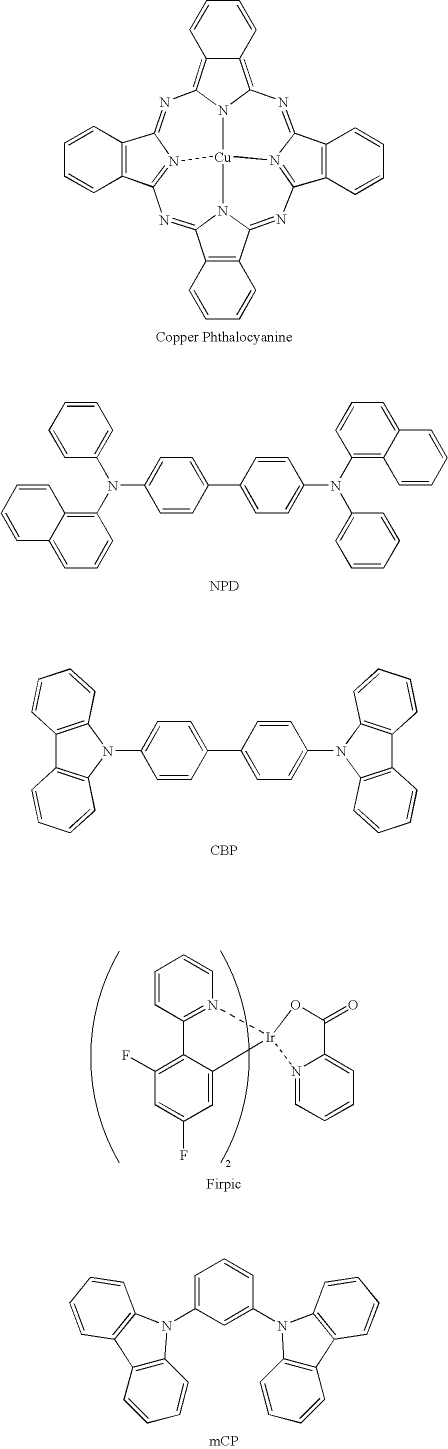

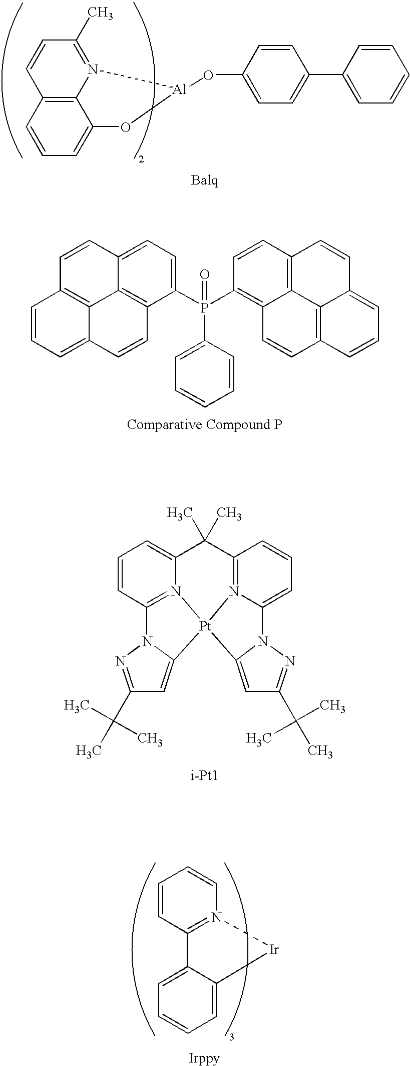

### Manufacture of the Device in Comparative Example 1

A glass substrate having an ITO film having a thickness of 0.5 mm and 2.5 cm square (manufactured by Geomatec Co., Ltd., surface resistance: 10Ω/□) is put in a washer and subjected to ultrasonic washing in 2-propanol, and then UV-ozone treatment for 30 minutes. The following organic compound layers are deposited in order on the transparent anode (ITO film) by vacuum deposition.

First layer: copper phthalocyanine: 10 nm
Second layer: NPD: 30 nm
Third layer: CBP and Firpic (weight ratio: 9/1): 50 nm
Fourth layer: BAlq: 40 nm

On these layers, lithium fluoride in a thickness of 0.1 nm and metal aluminum in a thickness of 100 nm are deposited in this order to prepare a cathode.

The glass substrate having the organic compound layers is put in a glove box replaced with argon gas without being in contact with the air and sealed with a stainless steel sealing can and a UV-curing type adhesive (XNR5516HV, manufactured by Nagase Ciba) to thereby obtain an organic electroluminescent device in Comparative Example 1.

T₁ level in the solid film of CBP is 60 kcal/mol. (A thin film was formed with the material on a cleaned quartz glass substrate in a thickness of about 50 nm by vacuum deposition. The spectrum of emission of phosphorescence of the thin film was measured with a fluorescence spectrophotometer Model F-7000 (manufactured by Hitachi High Technologies) under a liquid nitrogen temperature. The T₁ value was obtained by converting the rising wavelength at the end of the short wavelength side of the spectrum to energy.)

### Manufacture of the Device in Comparative Example 2

The organic electroluminescent device in Comparative Example 2 was manufactured in the same manner as in the manufacture of the device in Comparative Example 1 except for changing CBP to comparative compound P disclosed in JP-A-2006-73581.

### Manufacture of the Device in Example 1

The organic electroluminescent device in Example 1 was manufactured in the same manner as in the manufacture of the device in Comparative Example 1 except for changing CBP to the exemplified compound 1 of the invention.

### Manufacture of the device in Example 2

The organic electroluminescent device in Example 2 was manufactured in the same manner as in the manufacture of the device in Comparative Example 1 except for changing CBP to the exemplified compound 4 of the invention.

### Manufacture of the device in Example 3

The organic electroluminescent device in Example 3 was manufactured in the same manner as in the manufacture of the device in Comparative Example 1 except for changing CBP to the exemplified compound 7 of the invention.

### Evaluation of the Organic Electroluminescent Devices in Examples 1 to 3

Constant voltage was applied to the devices of Comparative Examples 1 and 2 and Examples 1 to 3 every 1 V in the range of from 1 V to 20 V. Emission originating in Firpic was not observed in the device of Comparative Example 2, but emission originating in Firpic was observed in the devices of Comparative Example 1 and Examples 1 to 3. The maximum values of external quantum efficiency were 4.9% in the device of Comparative Example 1, and 11.4%, 12.7% and 10.8% in the devices of Examples 1 to 3 respectively, and it was confirmed that the devices of Examples 1 to 3 had far better external quantum efficiency than that of Comparative Example 1.

### Manufacture of the device in Comparative Example 3

The organic electroluminescent device in Comparative Example 3 was manufactured in the same manner as in the manufacture of the device in Comparative Example 1 except for changing the organic compound layers as follows.

First layer: copper phthalocyanine: 10 nm
Second layer: NPD: 30 nm
Third layer: CBP and Irppy (weight ratio: 9/1): 50 nm
Fourth layer: BAlq: 40 nm

### Manufacture of the Device in Example 4

The organic electroluminescent device in Example 4 was manufactured in the same manner as in the manufacture of the device in Comparative Example 2 except for changing BAlq to the exemplified compound 1 of the invention.

### Manufacture of the Device in Example 5

The organic electroluminescent device in Example 5 was manufactured in the same manner as in the manufacture of the device in Comparative Example 2 except for changing BAlq to the exemplified compound 4 of the invention.

### Manufacture of the Device in Example 6

The organic electroluminescent device in Example 6 was manufactured in the same manner as in the manufacture of the device in Comparative Example 2 except for changing BAlq to the exemplified compound 7 of the invention.

### Evaluation of the Organic Electroluminescent Devices in Examples 4 to 6

Constant voltage was applied to the devices of Comparative Example 3 and Examples 4 to 6 every 1 V in the range of from 1 V to 20 V. Emission originating in Irppy was observed in all the devices. The maximum values of external quantum efficiency were 6.3% in the device of Comparative Example 3, and 13.8%, 14.4% and 14.1% in the devices of Examples 4 to 6 respectively, and it was confirmed that the devices of Examples 4 to 6 have far better external quantum efficiency than that of Comparative Example 3.

### Manufacture of the Device in Comparative Example 4

The organic electroluminescent device in Comparative Example 4 was manufactured in the same manner as in the manufacture of the device in Comparative Example 1 except for changing the third layer in Comparative Example 1 to the composition shown below.

Third layer: mCP and i-Pt1 (weight ratio: 95/5): 50 nm

### Manufacture of the Device in Example 7

The organic electroluminescent device in Example 7 was manufactured in the same manner as in the manufacture of the device in Comparative Example 4 except for changing the third layer in Comparative Example 4 to the composition shown below.

Third layer: mCP, i-Pt1 and exemplified compound 4 (weight ratio: 85/5/10): 50 nm

### Evaluation of the Device in Example 7

Constant voltage was applied to the devices of Comparative Example 4 and Example 7 every 1 V in the range of from 1 V to 20 V. Emission originating in i-Pt1 was observed in both devices. The maximum values of external quantum efficiency were 4.0% in the device of Comparative Example 4, and 8.1% in the device of Example 7, and it was confirmed that the device of Example 7 has far better external quantum efficiency than that of Comparative Example 4.

### Manufacture of the Device in Example 8

The organic electroluminescent device in Example 8 was manufactured in the same manner as in the manufacture of the device in Comparative Example 2 except for changing the organic compound layers as follows.

First layer: copper phthalocyanine: 10 nm
Second layer: NPD: 30 nm
Third layer: CBP and Irppy (weight ratio: 9/1): 50 nm
Fourth layer: BAlq: 30 nm
Fifth layer: exemplified compound 4: 10 nm

### Evaluation of the Device in Example 8

Constant voltage was applied to the device of Example 8 every 1 V in the range of from 1 V to 20 V. Emission originating in Irppy was observed in the device. The maximum value of external quantum efficiency was 7.7%. On measurement of the time required to reach half life of luminance by driving the devices of Example 8 and Comparative Example 3, the time of the device of Comparative Example 3 was 11 hours, while that of the device of Example 8 was 48 hours, and it was confirmed that the device of Example 8 had far longer life than that of Comparative Example 3. Half life of luminance was found by setting a device on OLED test system ST-D type (manufactured by TSK Co.) and driving the device on the condition of normal direction constant current of 0.4 mA by constant current mode, and measuring the time required for luminance to lower to 50% from the initial luminance as t_{0.5}.

### Manufacture of the Device in Comparative Example 5

The organic electroluminescent device in Comparative Example 5 was manufactured in the same manner as in the manufacture of the device in Comparative Example 1 except for changing the third layer in Comparative Example 1 to the composition shown below.

Third layer: mCP and D-24 (weight ratio: 95/5): 50 nm

### Manufacture of the Device in Example 9

The organic electroluminescent device in Example 9 was manufactured in the same manner as in the manufacture of the device in Comparative Example 4 except for changing the third layer of the device in Comparative Example 5 to the composition shown below.

Third layer: mCP, D-24 and exemplified compound 4 (weight ratio: 85/5/10): 50 nm

### Evaluation of the Device in Example 9

Constant voltage was applied to the devices of Comparative Example 5 and Example 9 every 1 V in the range of from 1 V to 20 V. Emission originating in D-24 was observed in both devices. The maximum values of external quantum efficiency were 4.1% in the device of Comparative Example 5 and 11.9% in the device of Example 9, and it was confirmed that the device of Example 9 had far better external quantum efficiency than that of Comparative Example 5.

### Manufacture of the Device in Comparative Example 6

The organic electroluminescent device in Comparative Example 6 was manufactured in the same manner as in the manufacture of the device in Comparative Example 1 except for changing the third layer in Comparative Example 1 to the composition shown below.

Third layer: mCP and D-35 (weight ratio: 95/5): 50 nm

### Manufacture of the Device in Example 10

The organic electroluminescent device in Example 10 was manufactured in the same manner as in the manufacture of the device in Comparative Example 6 except for changing the third layer of the device in Comparative Example 6 to the composition shown below.

Third layer: mCP, D-35 and exemplified compound 4 (weight ratio: 85/5/10): 50 nm

### Evaluation of the Device in Example 10

Constant voltage was applied to the devices of Comparative Example 6 and Example 10 every 1 V in the range of from 1 V to 20 V. Emission originating in D-35 was observed in both devices. The maximum values of external quantum efficiency were 5.3% in the device of Comparative Example 6 and 13.8% in the device of Example 10, and it was confirmed that the device of Example 10 had far better external quantum efficiency than that of Comparative Example 6.

### Manufacture of the Device in Comparative Example 7

The organic electroluminescent device in Comparative Example 7 was manufactured in the same manner as in the manufacture of the device in Comparative Example 1 except for changing the third layer in Comparative Example 1 to the composition shown below.

Third layer: mCP and D-51 (weight ratio: 95/5): 50 nm

### Manufacture of the Device in Example 11

The organic electroluminescent device in Example 11 was manufactured in the same manner as in the manufacture of the device in Comparative Example 7 except for changing the third layer of the device in Comparative Example 7 to the composition shown below.

Third layer: mCP, D-51 and exemplified compound 4 (weight ratio: 85/5/10): 50 nm

### Evaluation of the Device in Example 11

Constant voltage was applied to the devices of Comparative Example 7 and Example 11 every 1 V in the range of from 1 V to 20 V. Emission originating in D-51 was observed in both devices. The maximum values of external quantum efficiency were 4.2% in the device of Comparative Example 7 and 14.2% in the device of Example 11, and it was confirmed that the device of Example 11 had far better external quantum efficiency than that of Comparative Example 7.

### Manufacture of the Device in Example 12

The organic electroluminescent device in Example 12 was manufactured in the same manner as in the manufacture of the device in Comparative Example 1 except for changing CBP in Comparative Example 1 to the exemplified compound 40 of the invention.

### Manufacture of the Device in Example 13

The organic electroluminescent device in Example 13 was manufactured in the same manner as in the manufacture of the device in Comparative Example 1 except for changing CBP in Comparative Example 1 to the exemplified compound 41 of the invention.

### Manufacture of the Device in Example 14

The organic electroluminescent device in Example 14 was manufactured in the same manner as in the manufacture of the device in Comparative Example 1 except for changing CBP in Comparative Example 1 to the exemplified compound 42 of the invention.

Constant voltage was applied to the devices of Comparative Examples 1 and 2 and Examples 11 to 14 every 1 V in the range of from 1 V to 20 V. Emission originating in Firpic was not observed in the device of Comparative Example 2, but emission originating in Firpic was observed in the devices of Comparative Example 1 and Examples 11 to 14. The maximum values of external quantum efficiency are 4.9% in the device of Comparative Example 1, and 10.6%, 10.7% and 7.8% in the devices of Examples 11 to 14 respectively, and it was confirmed that the devices of Examples 11 to 14 had far better external quantum efficiency than that of Comparative Example 1.

### Manufacture of the Device in Example 15

The organic electroluminescent device in Example 15 was manufactured in the same manner as in the manufacture of the device in Comparative Example 5 except for changing the third layer of the device in Comparative Example 5 to the composition shown below.

Third layer: mCP, 8-4 and exemplified compound 40 (weight ratio: 85/5/10): 50 nm

### Evaluation of the Device in Example 15

Constant voltage was applied to the devices of Comparative Example 5 and Example 15 every 1 V in the range of from 1 V to 20 V. Emission originating in 8-4 was observed in both devices. The maximum values of external quantum efficiency were 4.1% in the device of Comparative Example 5 and 11.4% in the device of Example 15, and it was confirmed that the device of Example 15 had far better external quantum efficiency than that of Comparative Example 5.

### Manufacture of the Device in Example 16

The organic electroluminescent device in Example 16 was manufactured in the same manner as in the manufacture of the device in Comparative Example 5 except for changing the third layer of the device in Comparative Example 5 to the composition shown below.

Third layer: mCP, 8-4 and exemplified compound 2 (weight ratio: 85/5/10): 50 nm

### Evaluation of the Device in Example 16

Constant voltage was applied to the devices of Comparative Example 5 and Example 16 every 1 V in the range of from 1 V to 20 V. Emission originating in 8-4 was observed in both devices. The maximum values of external quantum efficiency were 4.1% in the device of Comparative Example 5 and 8.8% in the device of Example 16, and it was confirmed that the device of Example 16 had far better external quantum efficiency than that of Comparative Example 5.

### Manufacture of the Device in Example 17

The organic electroluminescent device in Example 17 was manufactured in the same manner as in the manufacture of the device in Comparative Example 5 except for changing the third layer of the device in Comparative Example 5 to the composition shown below.

Third layer: mCP, 8-4 and exemplified compound 52 (weight ratio: 85/5/10): 50 nm

### Evaluation of the Device in Example 17

Constant voltage was applied to the devices of Comparative Example 5 and Example 17 every 1 V in the range of from 1 V to 20 V. Emission originating in 8-4 was observed in both devices. The maximum values of external quantum efficiency were 4.1% in the device of Comparative Example 5 and 13.1% in the device of Example 17, and it was confirmed that the device of Example 17 had far better external quantum efficiency than that of Comparative Example 5.

It has been shown from the above example that an organic electroluminescent device of high efficiency and high durability can be obtained by using the compound of the invention.

While the invention has been described with reference to the exemplary embodiments, the technical scope of the invention is not restricted to the description of the exemplary embodiments. It is apparent to the skilled in the art that various changes or improvements can be made. It is apparent from the description of claims that the changed or improved configurations can also be included in the technical scope of the invention.

This application claims foreign priority from Japanese Patent Application No. 2007-78737, filed Mar. 26, 2007, the entire disclosure of which is herein incorporated by reference

What is claimed is:

1. An organic electroluminescent device comprising:
a pair of electrodes; and
an organic compound layer between the pair of electrodes, the organic compound layer including a light-emitting layer,
wherein the at least one organic compound layer contains at least one of a compound represent by formula (I) and a compound represented by formula (II): 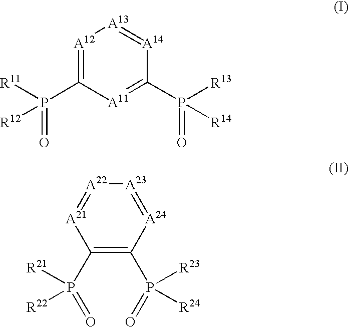
wherein R¹¹, R¹², R¹³ and R¹⁴ each independently represents a hydrogen atom or a substituent; A¹¹, A¹², A¹³ and A¹⁴ each independently represents a nitrogen atom or C—R¹⁰; R¹⁰ represents a hydrogen atom or a substituent, and when a plurality of R¹⁰'s are present, the plurality of R¹⁰'s may be the same or different and may be connected to each other to form a ring; R²¹, R²², R²³ and R²⁴ each independently represents a hydrogen atom or a substituent; A²¹, A²², A²³ and A²⁴ each independently represents a nitrogen atom or C—R²⁰; and R²⁰ represents a hydrogen atom or a substituent, and when a plurality of R²⁰'s are present, the plurality of R²⁰'s may be the same or different and may be connected to each other to form a ring.

2. The organic electroluminescent device according to claim 1, wherein each of the compound represented by formula (I) and a compound represented by formula (II) has a glass transition temperature of from 130 to 450° C.

3. The organic electroluminescent device according to claim 1, wherein the each of the compound represented by formula (I) and the compound represented by formula (II) has an energy level in the lowest triplet excited state of from 65 to 95 kcal/mol.

4. The organic electroluminescent device according to claim 1, wherein the at least one organic compound layer contains a light-emitting material, and the light-emitting material contains a phosphorescent material.

5. The organic electroluminescent device according to claim 4, wherein the phosphorescent material is an iridium complex or a platinum complex.

6. The organic electroluminescent device according to claim 5, wherein the phosphorescent material is a platinum complex having a tetradentate ligand.

7. The organic electroluminescent device according to claim 6, wherein the platinum complex having a tetradentate ligand is represented by formula (C-1): 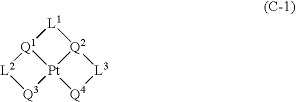
wherein Q¹, Q², Q³ and Q⁴ each independently represents a group coordinating to Pt; and L¹, L² and L³ each independently represents a single bond or a divalent linking group.

8. The organic electroluminescent device according to claim 7, wherein the platinum complex having a tetradentate ligand is represented by one of formulae (A), (B), (E) and (F): 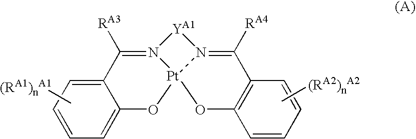
wherein R^{A3} and R^{A4} each independently represents a hydrogen atom or a substituent; R^{A1} and R^{A2} each independently represents a substituent, and when a plurality of R^{A1} and R^{A2} are present, the plurality of R^{A1} and R^{A2} may be the same or different, and R^{A1} and R^{A2} may be linked to each other to form a ring; n^{A1} and n^{A2} each independently represents an integer of from 0 to 4; and Y^{A1} represents a linking group; 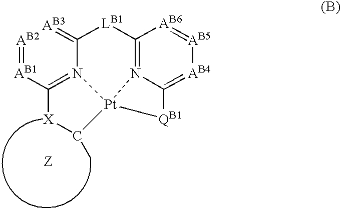
wherein A^{B1} to A^{B6} each independently represents C—R or N; R represents a hydrogen atom or a substituent; L^{B1} represents a single bond or a divalent linking group; X represents C or N; Z represents a 5- or 6-membered aromatic ring or aromatic heterocyclic ring formed together with X—C; and Q^{B1} represents an anionic group bonding to Pt; 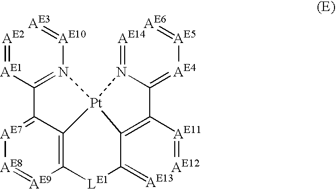
wherein A^{E1} to A^{E14} each independently represents C—R or N; R represents a hydrogen atom or a substituent; and L^{E1} represents a single bond or a divalent linking group; 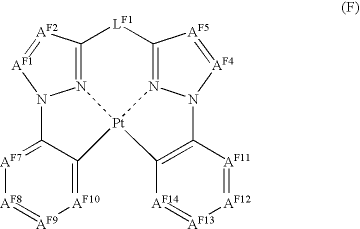
wherein A^{F1} to A^{F14} each independently represents C—R or N; R represents a hydrogen atom or a substituent; and L^{F1} represents a single bond or a divalent linking group.

9. The organic electroluminescent device according to claim 1, wherein the at least one of the compound represented by formula (I) and the compound represented by formula (II) is contained in the light-emitting layer.

10. The organic electroluminescent device according to claim 1, wherein the at least one organic compound layer includes a layer containing the at least one of the compound represented by formula (I) and the compound represented by formula (II), the layer being between the light-emitting layer and a cathode.

11. The organic electroluminescent device according to claim 1, wherein the at least one organic compound layer includes an electron transporting layer, and the at least one of the compound represented by formula (I) and the compound represented by formula (II) is contained in the electron transporting layer.

12. The organic electroluminescent device according to claim 1, wherein the at least one organic compound layer includes: a first layer containing the at least one of the compound represented by formula (I) and the compound represented by formula (II), the first layer being between the light-emitting layer and a cathode; and a second layer between the first layer and the light-emitting layer.

13. A compound represented by formula (I): 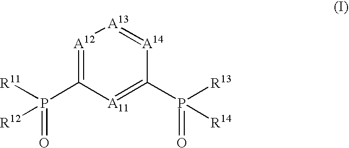
wherein R¹¹, R¹², R¹³ and R¹⁴ each independently represents a hydrogen atom or a substituent; A¹¹, A¹², A¹³ and A¹⁴ each independently represents a nitrogen atom or C—R¹⁰; and R¹⁰ represents a hydrogen atom or a substituent, and when a plurality of R¹⁰'s are present, the plurality of R¹⁰'s may be the same or different and may be connected to each other to form a ring.

14. A compound represented by formula (II): 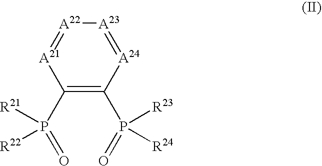
wherein R²¹, R²², R²³ and R²⁴ each independently represents a hydrogen atom or a substituent; A²¹, A²², A²³ and A²⁴ each independently represents a nitrogen atom or C—R²⁰;
and R²⁰ represents a hydrogen atom or a substituent, and when a plurality of R²⁰'s are present, the plurality of R²⁰'s may be the same or different and may be connected to each other to form a ringand may be connected to each other to form a ring.
